(19) United States
(12) Patent Application Publication
(10) Pub. No.: US 2024/0038866 A1
(43) Pub. Date: Feb. 1, 2024

(54) SEMICONDUCTOR DEVICE STRUCTURE WITH NANOSTRUCTURE AND METHOD FOR FORMING THE SAME

(71) Applicant: Taiwan Semiconductor Manufacturing Company, Ltd., Hsinchu (TW)

(72) Inventors: Chih-Ching WANG, Kinmen County (TW); Chung-I YANG, Hsinchu City (TW); Wei-Yang LEE, Taipei City (TW); Wen-Hsing HSIEH, Hsinchu City (TW)

(73) Assignee: Taiwan Semiconductor Manufacturing Company, Ltd., Hsinchu (TW)

(21) Appl. No.: 17/875,975

(22) Filed: Jul. 28, 2022

(51) Int. Cl. H01L 29/423; H01L 29/06; H01L 29/786; H01L 29/417; H01L 29/66

(52) U.S. Cl. CPC H01L 29/42392; H01L 29/0673; H01L 29/78696; H01L 29/41775; H01L 29/66553; H01L 29/66545; H01L 29/6656

(57) ABSTRACT

A method for forming a semiconductor device structure is provided. The method includes providing a substrate. The method includes forming a nanostructure stack over the substrate. The method includes forming a gate stack over the nanostructure stack and the substrate. The method includes removing the first nanostructure forming a first gap between the substrate and the second nanostructure. The method includes forming a first spacer layer in the first gap and a gate spacer over a sidewall of the gate stack. The method includes partially removing the nanostructure stack, which is not covered by the gate stack and the gate spacer, to form a first trench in the nanostructure stack. The method includes forming a source/drain structure in the first trench and over the first spacer layer.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1N are cross-sectional views of various stages of a process for forming a semiconductor device structure, in accordance with some embodiments.

FIG. 1A-1 is a perspective view of the semiconductor device structure of FIG. 1A, in accordance with some embodiments.

FIG. 1E-1 is a perspective view of the semiconductor device structure of FIG. 1E, in accordance with some embodiments.

FIG. 1N-1 is a perspective view of the semiconductor device structure of FIG. 1N, in accordance with some embodiments.

FIG. 1N-2 is a cross-sectional view illustrating the semiconductor device structure along a sectional line II-II′ in FIG. 1N-1, in accordance with some embodiments.

FIG. 1N-3 is a cross-sectional view illustrating the semiconductor device structure along a sectional line in FIG. 1N-1, in accordance with some embodiments.

FIGS. 2A-2L are cross-sectional views of various stages of a process for forming a semiconductor device structure, in accordance with some embodiments.

FIG. 2C-1 is a perspective view of the semiconductor device structure of FIG. 2C, in accordance with some embodiments.

FIG. 2L-1 is a perspective view of the semiconductor device structure of FIG. 2L, in accordance with some embodiments.

FIG. 2L-2 is a cross-sectional view illustrating the semiconductor device structure along a sectional line II-II′ in FIG. 2L-1, in accordance with some embodiments.

FIG. 2L-3 is a cross-sectional view illustrating the semiconductor device structure along a sectional line III-III′ in FIG. 2L-1, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure. Source/drain structure(s) may refer to a source or a drain, individually or collectively dependent upon the context.

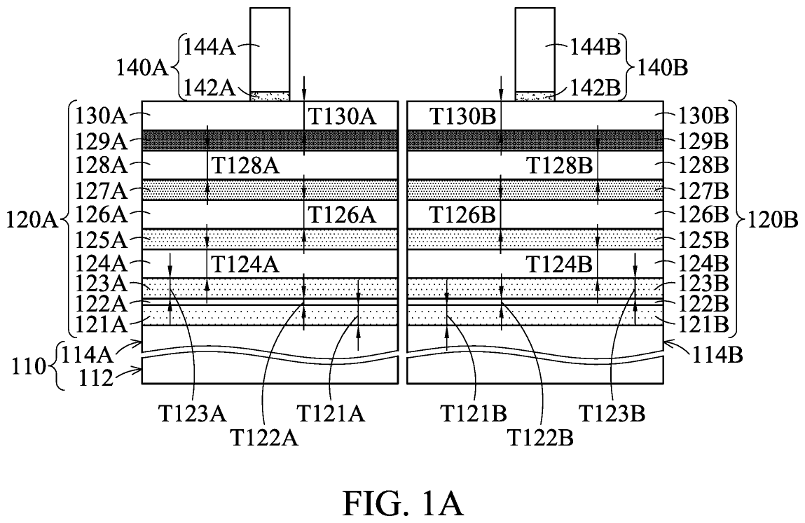

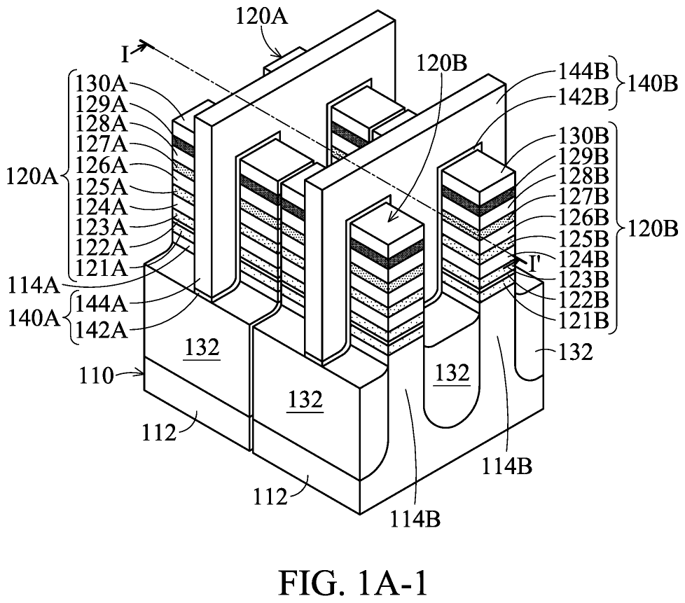

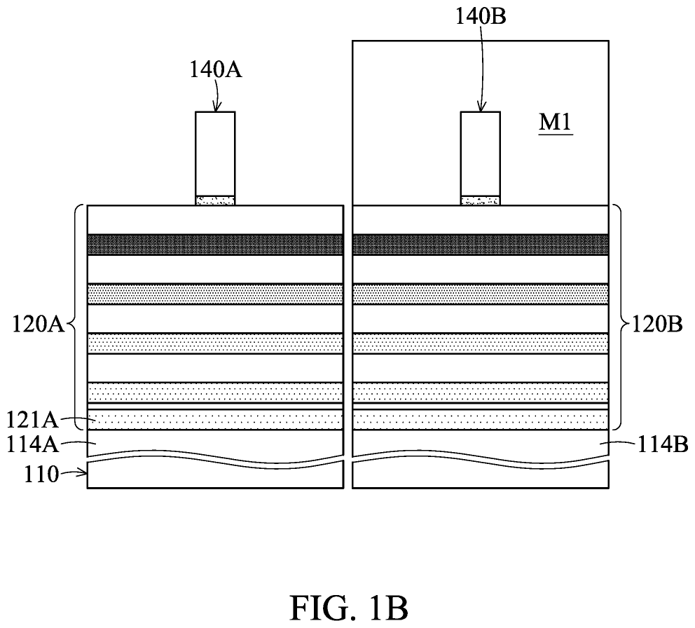

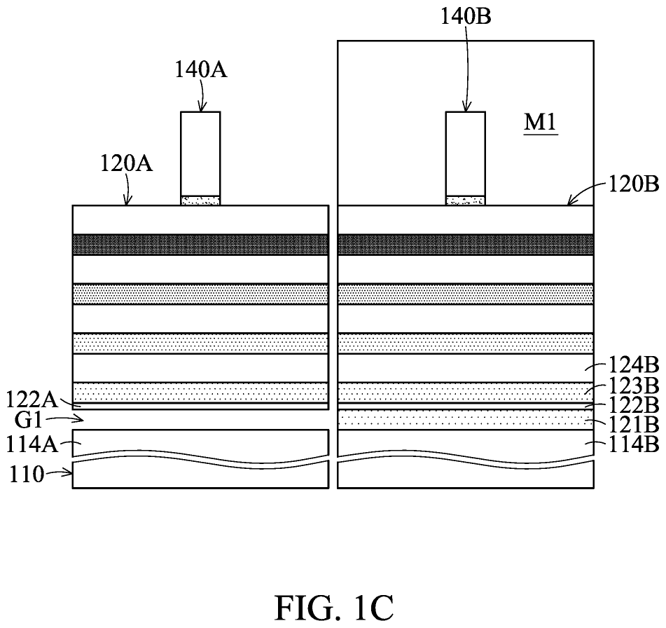

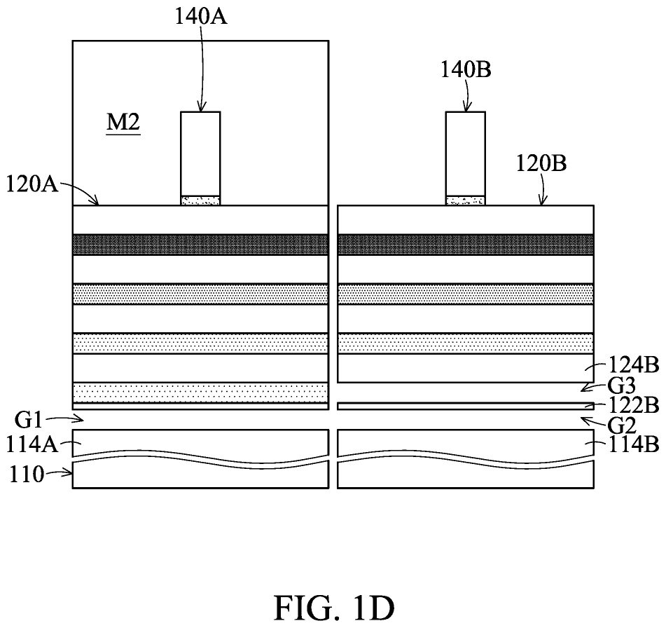

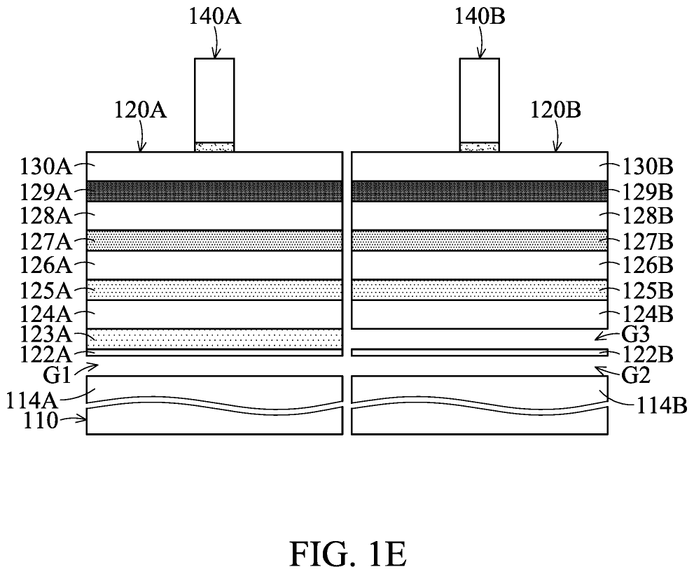

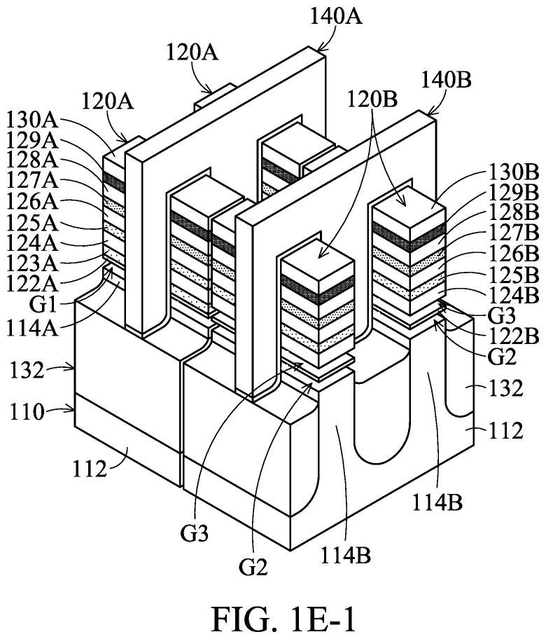

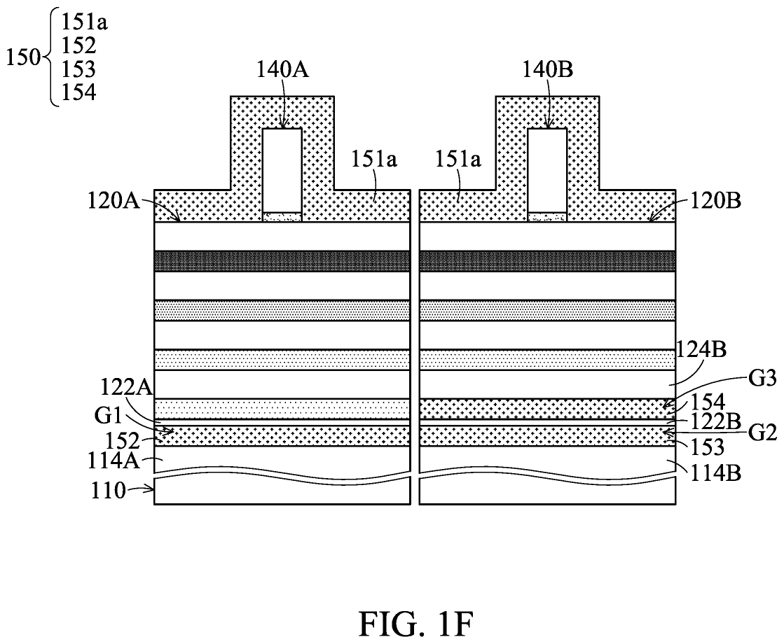

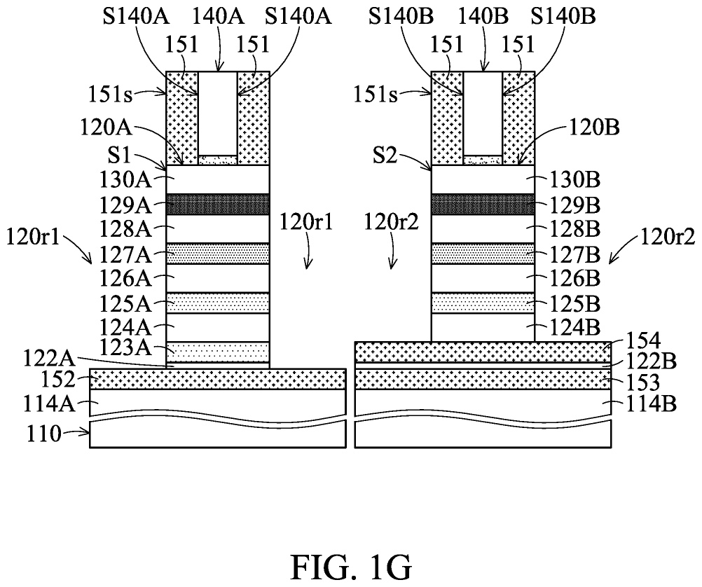

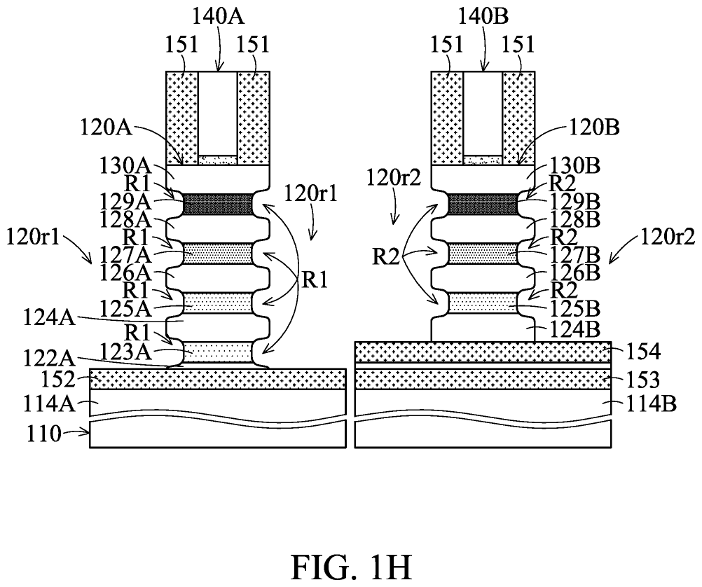

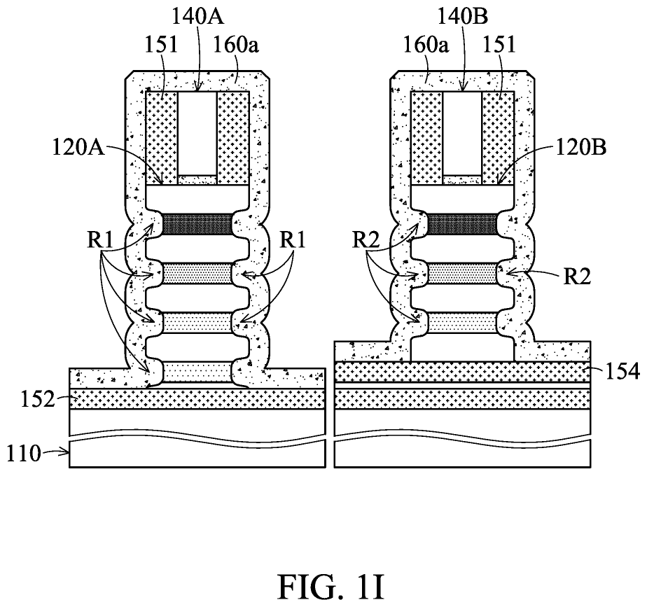

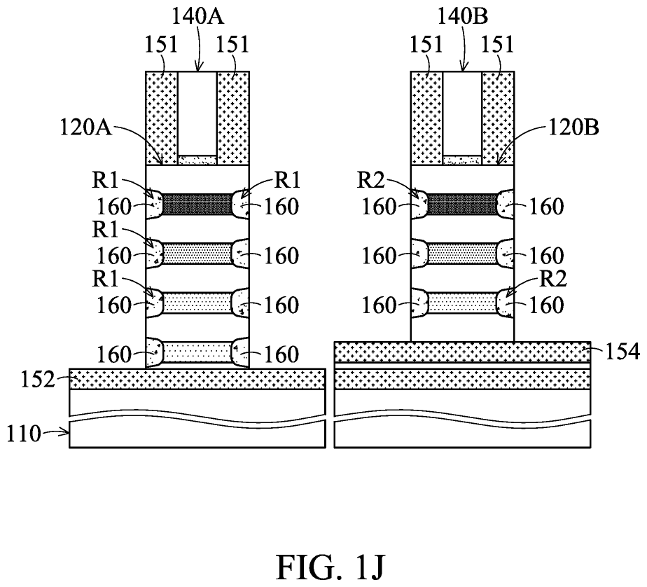

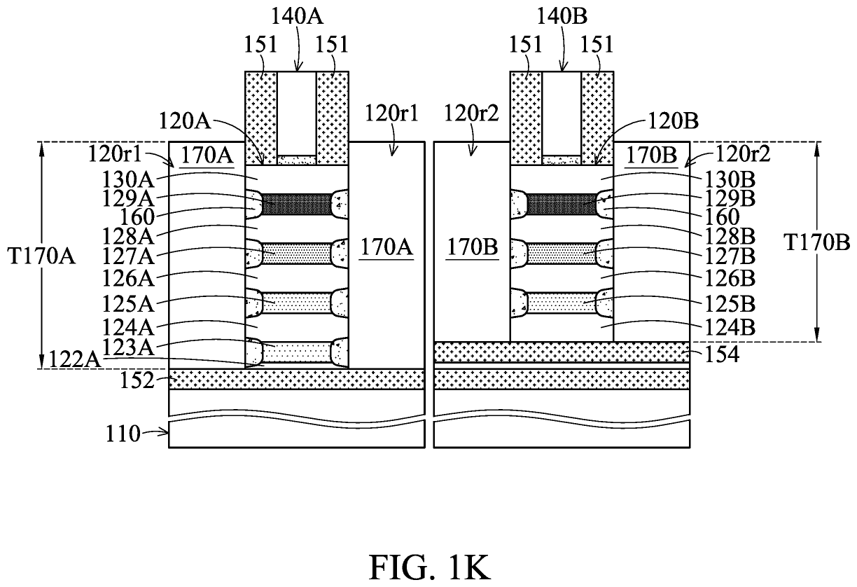

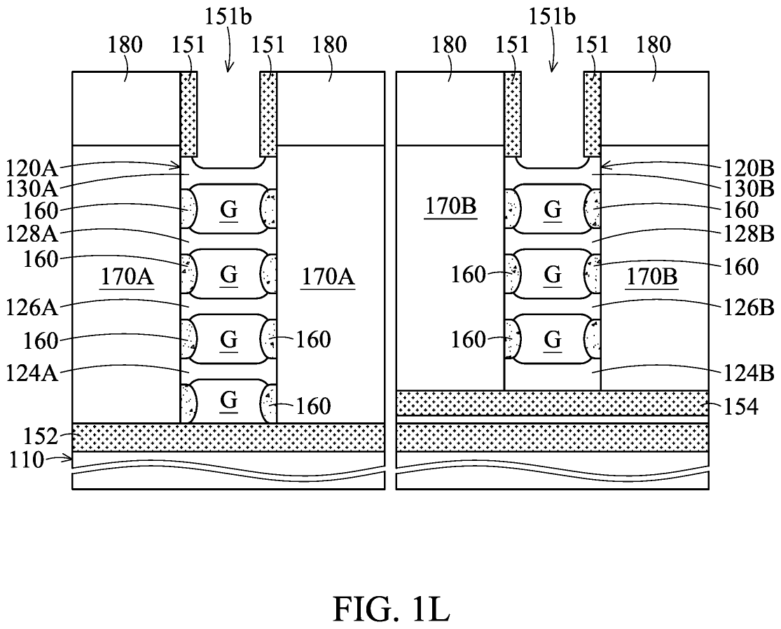

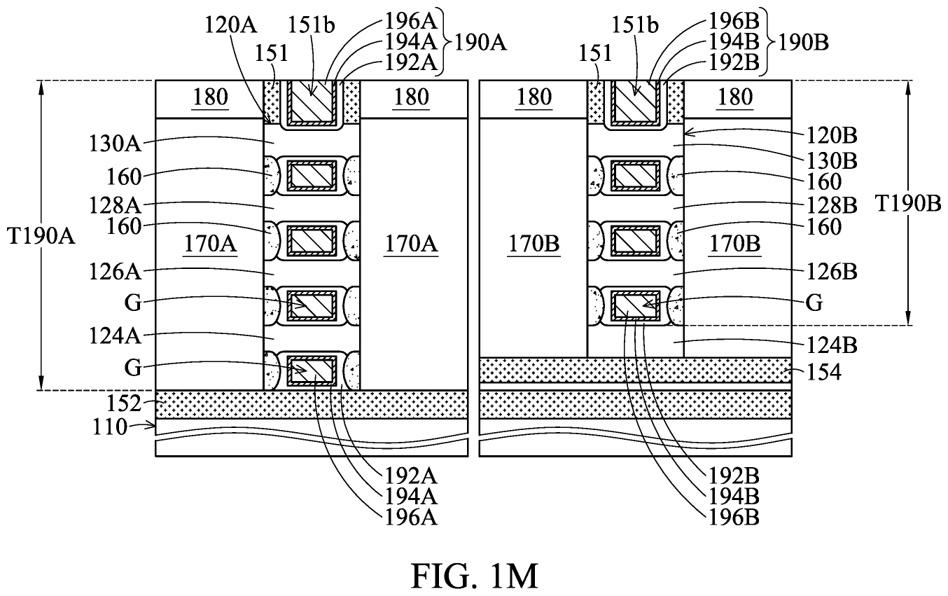

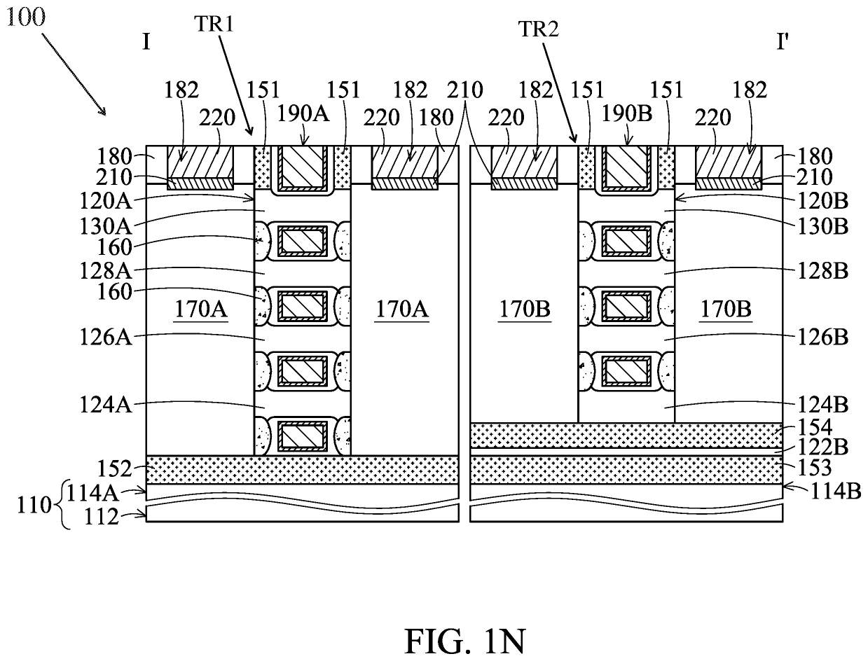

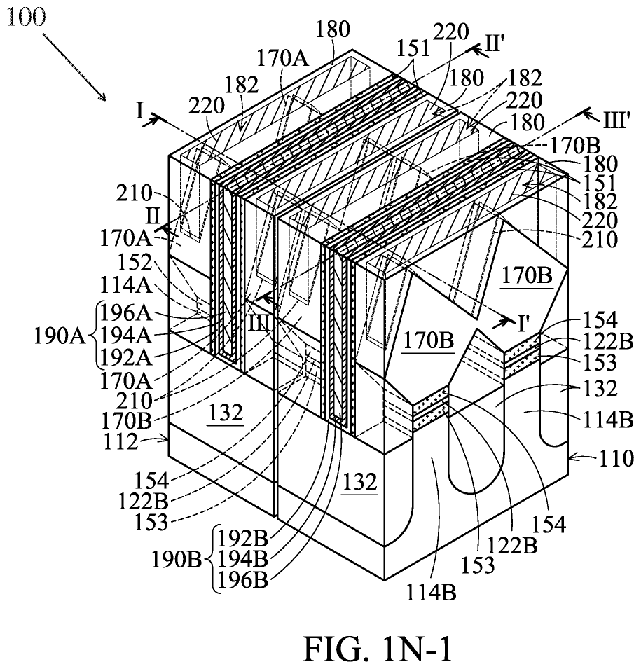

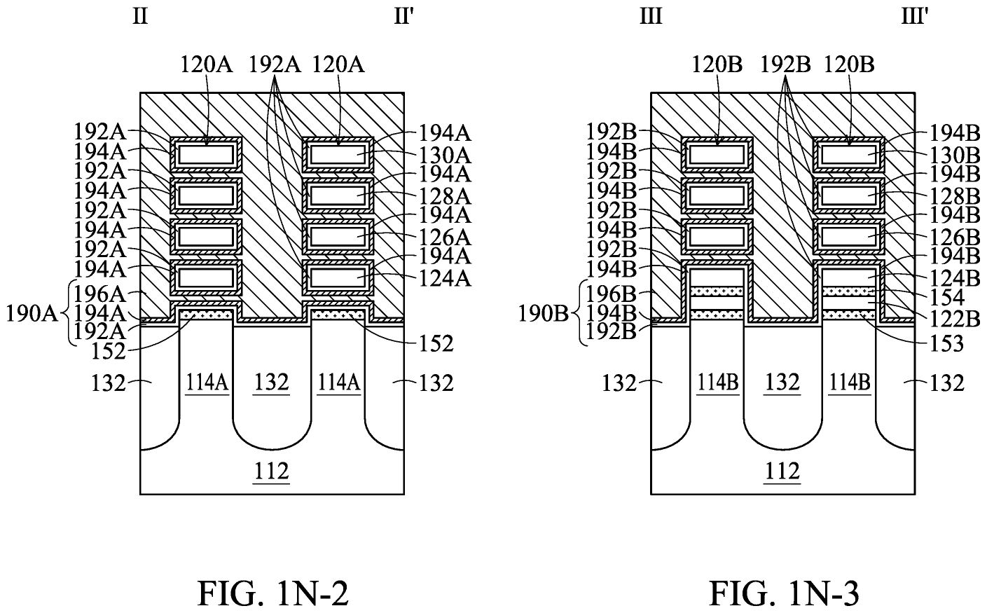

FIGS. 1A-1N are cross-sectional views of various stages of a process for forming a semiconductor device structure, in accordance with some embodiments. FIG. 1A-1 is a perspective view of the semiconductor device structure of FIG. 1A, in accordance with some embodiments.

As shown in FIGS. 1A and 1A-1, a substrate 110 is provided, in accordance with some embodiments. The substrate 110 has a base 112 and fins 114A and 114B over the base 112, in accordance with some embodiments. The substrate 110 includes, for example, a semiconductor substrate. The substrate 110 includes, for example, a semiconductor wafer (such as a silicon wafer) or a portion of a semiconductor wafer.

In some embodiments, the substrate 110 is made of an elementary semiconductor material including silicon or germanium in a single crystal structure, a polycrystal structure, or an amorphous structure. In some other embodiments, the substrate 110 is made of a compound semiconductor, such as silicon carbide, gallium arsenide, gallium phosphide, indium phosphide, indium arsenide, an alloy semiconductor, such as SiGe or GaAsP, or a combination thereof. The substrate 110 may also include multi-layer semiconductors, semiconductor on insulator (SOI) (such as silicon on insulator or germanium on insulator), or a combination thereof.

In some embodiments, the substrate 110 is a device wafer that includes various device elements. In some embodiments, the various device elements are formed in and/or over the substrate 110. The device elements are not shown in figures for the purpose of simplicity and clarity. Examples of the various device elements include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to surround active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

As shown in FIGS. 1A and 1A-1, nanostructure stacks 120A and 120B are formed over the fins 114A and 114B respectively, in accordance with some embodiments. The nanostructure stack 120A includes nanostructures 121A, 122A, 123A, 124A, 125A, 126A, 127A, 128A, 129A, and 130A, in accordance with some embodiments.

The nanostructures 121A, 122A, 123A, 124A, 125A, 126A, 127A, 128A, 129A, and 130A are sequentially stacked over the fin 114A, in accordance with some embodiments. The nanostructures 121A, 122A, 123A, 124A, 125A, 126A, 127A, 128A, 129A, and 130A include nanowires or nanosheets, in accordance with some embodiments.

The nanostructure 122A is thinner than the nanostructure 121A, 123A, 124A, 125A, 126A, 127A, 128A, 129A, or 130A, in accordance with some embodiments. The nanostructure 121A has a thickness T121A ranging from about 5 nm to about 10 nm, in accordance with some embodiments. The nanostructure 122A has a thickness T122A ranging from about 1 nm to about 3 nm, in accordance with some embodiments. The nanostructure 123A has a thickness T123A ranging from about 5 nm to about 10 nm, in accordance with some embodiments.

The nanostructure 124A has a thickness T124A ranging from about 5 nm to about 10 nm, in accordance with some embodiments. The nanostructure 126A has a thickness T126A ranging from about 5 nm to about 10 nm, in accordance with some embodiments. The nanostructure 128A has a thickness T128A ranging from about 5 nm to about 10 nm, in accordance with some embodiments. The nanostructure 130A has a thickness T130A ranging from about 5 nm to about 10 nm, in accordance with some embodiments.

The nanostructure stack 120B includes nanostructures 121B, 122B, 123B, 124B, 125B, 126B, 127B, 128B, 129B, and 130B, in accordance with some embodiments. The nanostructures 121B, 122B, 123B, 124B, 125B, 126B, 127B, 128B, 129B, and 130B are sequentially stacked over the fin 114B, in accordance with some embodiments. The nanostructures 121B, 122B, 123B, 124B, 125B, 126B, 127B, 128B, 129B, and 130B include nanowires or nanosheets, in accordance with some embodiments.

The nanostructure 122B is thinner than the nanostructure 121B, 123B, 124B, 125B, 126B, 127B, 128B, 129B, or 130B, in accordance with some embodiments. The nanostructure 121B has a thickness T121B ranging from about 5 nm to about 10 nm, in accordance with some embodiments. The nanostructure 122B has a thickness T122B ranging from about 1 nm to about 3 nm, in accordance with some embodiments. The nanostructure 123B has a thickness T123B ranging from about 5 nm to about 10 nm, in accordance with some embodiments.

The nanostructure 124B has a thickness T124B ranging from about 5 nm to about 10 nm, in accordance with some embodiments. The nanostructure 126B has a thickness T126B ranging from about 5 nm to about 10 nm, in accordance with some embodiments. The nanostructure 128B has a thickness T128B ranging from about 5 nm to about 10 nm, in accordance with some embodiments. The nanostructure 130B has a thickness T130B ranging from about 5 nm to about 10 nm, in accordance with some embodiments.

The nanostructures 121A, 121B, 123A, 123B, 125A, 125B, 127A, 127B, 129A, and 129B include a first material, in accordance with some embodiments. The first material is different from the material of the substrate 110, in accordance with some embodiments. The first material includes an alloy semiconductor, such as silicon germanium (SiGe), in accordance with some embodiments.

In some embodiments, a germanium concentration of the nanostructure 121A or 121B is greater than a germanium concentration of the nanostructure 123A or 123B. In some embodiments, the germanium concentration of the nanostructure 123A or 123B is greater than a germanium concentration of the nanostructure 125A or 125B.

In some embodiments, the germanium concentration of the nanostructure 125A or 125B is greater than a germanium concentration of the nanostructure 127A or 127B. In some embodiments, the germanium concentration of the nanostructure 127A or 127B is greater than a germanium concentration of the nanostructure 129A or 129B.

The germanium concentration of the nanostructure 121A or 121B ranges from about 35 at % to about 50 at %, in accordance with some embodiments. The germanium concentration of the nanostructure 123A or 123B ranges from about 25 at % to about 35 at %, in accordance with some embodiments. The germanium concentration of the nanostructure 125A or 125B ranges from about 20 at % to about 25 at %, in accordance with some embodiments.

The germanium concentration of the nanostructure 127A or 127B ranges from about 15 at % to about 20 at %, in accordance with some embodiments. The germanium concentration of the nanostructure 129A or 129B ranges from about 15 at % to about 20 at %, in accordance with some embodiments.

The higher the germanium concentration is, the higher the etch rate is, in accordance with some embodiments. Therefore, an etch rate of the nanostructure 121A or 121B is greater than an etch rate of the nanostructure 123A or 123B. In some embodiments, the etch rate of the nanostructure 123A or 123B is greater than an etch rate of the nanostructure 125A or 125B.

In some embodiments, the etch rate of the nanostructure 125A or 125B is greater than an etch rate of the nanostructure 127A or 127B. In some embodiments, the etch rate of the nanostructure 127A or 127B is greater than an etch rate of the nanostructure 129A or 129B.

The nanostructures 121A, 121B, 123A, and 123B are optionally doped with a group VA element such as phosphorus (P), which is able to improve the etch rate of the nanostructures 121A, 121B, 123A, and 123B, in accordance with some embodiments. The phosphorus concentration of the nanostructure 121A, 121B, 123A, or 123B ranges from about 1E18 cm⁻³ to about 1E20 cm⁻³, in accordance with some embodiments.

The nanostructures 125A, 125B, 127A, 127B, 129A, and 129B are optionally doped with a group IIIA element such as boron (B), which is able to reduce the etch rate of the nanostructures 125A, 125B, 127A, 127B, 129A, and 129B, in accordance with some embodiments. The boron concentration of the nanostructure 125A, 125B, 127A, 127B, 129A, or 129B ranges from about 1E18 cm⁻³ to about 1E20 cm⁻³, in accordance with some embodiments.

The nanostructures 122A, 122B, 124A, 124B, 126A, 126B, 128A, 128B, 130A, and 130B are all made of the same second material, in accordance with some embodiments. The second material is different from the first material, in accordance with some embodiments. The second material is the same as the material of the substrate 110, in accordance with some embodiments. The second material includes an elementary semiconductor material including silicon or germanium in a single crystal structure, a polycrystal structure, or an amorphous structure, in accordance with some embodiments.

The second material includes a compound semiconductor, such as silicon carbide, gallium arsenide, gallium phosphide, indium phosphide, indium arsenide, an alloy semiconductor, such as SiGe or GaAsP, or a combination thereof, in accordance with some embodiments.

As shown in FIGS. 1A and 1A-1, an isolation layer 132 is formed over the base 112, in accordance with some embodiments. The fins 114A and 114B are partially embedded in the isolation layer 132, in accordance with some embodiments. The fins 114A and 114B are surrounded by the isolation layer 132, in accordance with some embodiments.

The isolation layer 132 is made of a dielectric material such as an oxide-containing material (e.g., silicon oxide), an oxynitride-containing material (e.g., silicon oxynitride), a low-k (low dielectric constant) material, a porous dielectric material, glass, or a combination thereof, in accordance with some embodiments. The glass includes borosilicate glass (PSG), phosphoric silicate glass (PSG), borophosphosilicate glass (BPSG), fluorinated silicate glass (FSG), or a combination thereof, in accordance with some embodiments.

The isolation layer 132 is formed using a deposition process (or a spin-on process), a chemical mechanical polishing process, and an etching back process, in accordance with some embodiments. The deposition process includes a chemical vapor deposition (CVD) process, a high density plasma chemical vapor deposition (HDPCVD) process, a flowable chemical vapor deposition (FCVD) process, a sputtering process, or a combination thereof, in accordance with some embodiments.

As shown in FIGS. 1A and 1A-1, gate stacks 140A and 140B are formed over the nanostructure stacks 120A and 120B respectively, in accordance with some embodiments. Specifically, the gate stack 140A is formed over the nanostructure stack 120A, the fin 114A, and the isolation layer 132, in accordance with some embodiments. The gate stack 140B is formed over the nanostructure stack 120B, the fin 114B, and the isolation layer 132, in accordance with some embodiments.

The gate stack 140A includes a gate dielectric layer 142A and a gate electrode 144A, in accordance with some embodiments. The gate electrode 144A is over the gate dielectric layer 142A, in accordance with some embodiments. The gate dielectric layer 142A is positioned between the gate electrode 144A and the nanostructure stack 120A, in accordance with some embodiments.

The gate dielectric layer 142A is also positioned between the gate electrode 144A and the fin 114A, in accordance with some embodiments. The gate dielectric layer 142A is positioned between the gate electrode 144A and the isolation layer 132, in accordance with some embodiments.

The gate dielectric layer 142A is made of an oxide-containing material such as silicon oxide, in accordance with some embodiments. The gate dielectric layer 142A is formed using a chemical vapor deposition process and an etching process, in accordance with some embodiments. The gate electrode 144A is made of a semiconductor material such as polysilicon, in accordance with some embodiments. The gate electrode 144A is formed using a chemical vapor deposition process and an etching process, in accordance with some embodiments.

The gate stack 140B includes a gate dielectric layer 142B and a gate electrode 144B, in accordance with some embodiments. The gate electrode 144B is over the gate dielectric layer 142B, in accordance with some embodiments. The gate dielectric layer 142B is positioned between the gate electrode 144B and the nanostructure stack 120B, in accordance with some embodiments.

The gate dielectric layer 142B is also positioned between the gate electrode 144B and the fin 114B, in accordance with some embodiments. The gate dielectric layer 142B is positioned between the gate electrode 144B and the isolation layer 132, in accordance with some embodiments.

The gate dielectric layer 142B is made of an oxide-containing material such as silicon oxide, in accordance with some embodiments. The gate dielectric layer 142B is formed using a chemical vapor deposition process and an etching process, in accordance with some embodiments. The gate electrode 144B is made of a semiconductor material such as polysilicon, in accordance with some embodiments. The gate electrode 144B is formed using a chemical vapor deposition process and an etching process, in accordance with some embodiments.

As shown in FIG. 1B, a mask layer M1 is formed over the gate stack 140B, the nanostructure stack 120B, and the fin 114B, in accordance with some embodiments. The mask layer M1 is made of a material, which is different from that of the gate stacks 140A and 140B, the nanostructure stacks 120A and 120B, and the fins 114A and 114B, in accordance with some embodiments. The material includes nitrides (e.g., SiN) or polymer (e.g., a photoresist material), in accordance with some embodiments.

As shown in FIG. 1C, the nanostructure 121A is removed to form a gap G1 in the nanostructure stack 120A, in accordance with some embodiments. The gap G1 is between the fin 114A and the nanostructure 122A, in accordance with some embodiments. The removal process includes an etching process such as a dry etching process or a wet etching process, in accordance with some embodiments.

As shown in FIG. 1D, the mask layer M1 is removed, in accordance with some embodiments. As shown in FIG. 1D, a mask layer M2 is formed over the gate stack 140A, the nanostructure stack 120A, and the fin 114A, in accordance with some embodiments. The mask layer M2 is made of a material, which is different from that of the gate stacks 140A and 140B, the nanostructure stacks 120A and 120B, and the fins 114A and 114B, in accordance with some embodiments. The material includes nitrides (e.g., SiN) or polymer (e.g., a photoresist material), in accordance with some embodiments.

As shown in FIGS. 1C and 1D, the nanostructures 121B and 123B are removed to form gaps G2 and G3 in the nanostructure stack 120B, in accordance with some embodiments. The gap G2 is between the fin 114B and the nanostructure 122B, in accordance with some embodiments. The gap G3 is between the nanostructures 122B and 124B, in accordance with some embodiments. The removal process includes an etching process such as a dry etching process or a wet etching process, in accordance with some embodiments.

FIG. 1E-1 is a perspective view of the semiconductor device structure of FIG. 1E, in accordance with some embodiments. As shown in FIGS. 1E and 1E-1, the mask layer M2 is removed, in accordance with some embodiments.

As shown in FIG. 1F, a dielectric layer 150 is formed over the gate stacks 140A and 140B and the nanostructure stacks 120A and 120B and in the gap G1 of the nanostructure stack 120A and the gaps G2 and G3 of the nanostructure stack 120B, in accordance with some embodiments. The dielectric layer 150 includes a gate spacer layer 151a and spacer layers 152, 153, and 154, in accordance with some embodiments.

The gate spacer layer 151a is over the gate stacks 140A and 140B and the nanostructure stacks 120A and 120B, in accordance with some embodiments. The spacer layers 152, 153, and 154 are in the gaps G1, G2, and G3 respectively, in accordance with some embodiments. The nanostructure 122B is between the spacer layers 153 and 154, in accordance with some embodiments. The spacer layer 153 is between the nanostructure 122B and the fin 114B of the substrate 110, in accordance with some embodiments. The nanostructure 122A or 122B is thinner than the spacer layer 152, 153, or 154, in accordance with some embodiments.

The dielectric layer 150 includes insulating materials, such as oxides (e.g., silicon oxide), nitrides (e.g., silicon nitride or silicon oxynitride, or carbides (e.g., silicon carbide), in accordance with some embodiments. The dielectric layer 150 is made of a material different from that of the gate stacks 140A and 140B, in accordance with some embodiments.

The formation of the dielectric layer 150 includes a deposition process, in accordance with some embodiments. The deposition process includes a chemical vapor deposition (CVD) process, a high density plasma chemical vapor deposition (HDPCVD) process, a flowable chemical vapor deposition (FCVD) process, or a combination thereof, in accordance with some embodiments.

As shown in FIG. 1G, portions of the gate spacer layer 151a are removed, in accordance with some embodiments. The remaining gate spacer layer 151a forms a gate spacer 151, in accordance with some embodiments. The gate spacer 151 is over sidewalls S140A of the gate stack 140A and sidewalls S140B of the gate stack 140B, in accordance with some embodiments. The gate spacer 151 surrounds the gate stacks 140A and 140B, in accordance with some embodiments.

The gate spacer 151 is positioned over the nanostructure stacks 120A and 120B and the fins 114A and 114B, in accordance with some embodiments. The removal process includes an etching process such as an anisotropic etching process (e.g., a dry etching process), in accordance with some embodiments.

As shown in FIG. 1G, end portions of the nanostructures 122A, 123A, 124A, 124B, 125A, 125B, 126A, 126B, 127A, 127B, 128A, 128B, 129A, 129B, 130A, and 130B, which are not covered by the gate stacks 140A and 140B and the gate spacer 151, are removed, in accordance with some embodiments. The removal process forms trenches 120r1 and 120r2 in the nanostructure stacks 120A and 120B respectively, in accordance with some embodiments.

The trenches 120r1 expose portions of the spacer layer 152, in accordance with some embodiments. The trenches 120r2 expose portions of the spacer layer 154, in accordance with some embodiments. After the removal process, sidewalls S1 of the nanostructure stack 120A are substantially aligned with (or substantially coplanar with) sidewalls 151s of the gate spacer 151 over the nanostructure stack 120A, in accordance with some embodiments.

In some embodiments, sidewalls S2 of the nanostructure stack 120B are substantially aligned with (or substantially coplanar with) sidewalls 151s of the gate spacer 151 over the nanostructure stack 120B, in accordance with some embodiments. The removal process includes an etching process, in accordance with some embodiments. The etching process includes an anisotropic etching process such as a dry etching process, in accordance with some embodiments.

As shown in FIG. 1H, portions of the nanostructures 123A, 125A, 125B, 127A, 127B, 129A, and 129B are removed through the trenches 120r1 and 120r2, in accordance with some embodiments. The removal process forms recesses R1 and R2 in the nanostructure stacks 120A and 120B respectively, in accordance with some embodiments.

The recesses R1 are between the nanostructures 122A, 124A, 126A, 128A, and 130A, in accordance with some embodiments. The recesses R2 are between the nanostructures 124B, 126B, 128B, and 130B, in accordance with some embodiments. The removal process further removes portions of the nanostructures 122A, 124A, 124B, 126A, 126B, 128A, 128B, 130A, and 130B, in accordance with some embodiments. The removal process includes an etching process such as a dry etching process or a wet etching process, in accordance with some embodiments.

As shown in FIG. 1I, an inner spacer layer 160a is formed over the gate stacks 140A and 140B, the nanostructure stacks 120A and 120B, and the spacer layers 152 and 154 and in the recesses R1 and R2 of the nanostructure stacks 120A and 120B, in accordance with some embodiments.

The inner spacer layer 160a is made of an insulating material, such as an oxide-containing material (e.g., silicon oxide), a nitride-containing material (e.g., silicon nitride), an oxynitride-containing material (e.g., silicon oxynitride), a carbide-containing material (e.g., silicon carbide), a high-k material (e.g., HfO₂, ZrO₂, HfZrO₂, or Al₂O₃), or a low-k material, in accordance with some embodiments.

The term “high-k material” means a material having a dielectric constant greater than the dielectric constant of silicon dioxide, in accordance with some embodiments. The term “low-k material” means a material having a dielectric constant less than the dielectric constant of silicon dioxide, in accordance with some embodiments.

In some embodiments, the inner spacer layer 160a is formed using a deposition process. The deposition process includes a physical vapor deposition process, a chemical vapor deposition process, an atomic layer deposition process, or the like, in accordance with some embodiments.

As shown in FIG. 1J, portions of the inner spacer layer 160a outside of the recesses R1 and R2 of the nanostructure stacks 120A and 120B are removed, in accordance with some embodiments. The remaining inner spacer layer 160a forms an inner spacer 160, in accordance with some embodiments. The inner spacer 160 is in the recesses R1 and R2, in accordance with some embodiments.

The inner spacer 160 is in direct contact with the nanostructure stacks 120A and 120B, in accordance with some embodiments. The inner spacer 160 is in direct contact with the spacer layer 152, in accordance with some embodiments. The removal process includes an etching process such as an anisotropic etching process (e.g., a dry etching process), in accordance with some embodiments.

As shown in FIG. 1K, source/drain structures 170A are formed in the trenches 120r1 and over the spacer layer 152, in accordance with some embodiments. The nanostructures 122A, 124A, 126A, 128A, and 130A are between the source/drain structures 170A, in accordance with some embodiments.

The source/drain structures 170A are in direct contact with (or connected to) the nanostructures 124A, 126A, 128A, and 130A, the gate spacer 151, and the inner spacer 160, in accordance with some embodiments. The source/drain structures 170A are in direct contact with the spacer layer 152, in accordance with some embodiments. The source/drain structures 170A are used to be a source structure and a drain structure, in accordance with some embodiments.

In some embodiments, the source/drain structures 170A are made of a semiconductor material (e.g., silicon germanium). In some embodiments, the source/drain structures 170A are doped with P-type dopants. The P-type dopants include the Group IIIA element, in accordance with some embodiments. The Group IIIA element includes boron or another suitable material.

In some other embodiments, the source/drain structures 170A are made of a semiconductor material (e.g., silicon or silicon carbide). The source/drain structures 170A are doped with N-type dopants, such as the Group VA element, in accordance with some embodiments. The Group VA element includes phosphor (P), antimony (Sb), or another suitable Group VA material. The source/drain structures 170A are formed using an epitaxial process, in accordance with some embodiments.

As shown in FIG. 1K, source/drain structures 170B are formed in the trenches 120r2 and over the spacer layer 154, in accordance with some embodiments. The nanostructures 124B, 126B, 128B, and 130B are between the source/drain structures 170B, in accordance with some embodiments. The source/drain structures 170B are in direct contact with (or connected to) the nanostructures 124B, 126B, 128B, and 130B, the gate spacer 151, and the inner spacer 160, in accordance with some embodiments.

The source/drain structures 170B are in direct contact with the spacer layer 154, in accordance with some embodiments. The source/drain structures 170B are used to be a source structure and a drain structure, in accordance with some embodiments. The thickness T170A of the source/drain structure 170A is greater than the thickness T170B of the source/drain structure 170B, in accordance with some embodiments.

In some embodiments, the source/drain structures 170B are made of a semiconductor material (e.g., silicon germanium). In some embodiments, the source/drain structures 170B are doped with P-type dopants. The P-type dopants include the Group IIIA element, in accordance with some embodiments. The Group IIIA element includes boron or another suitable material.

In some other embodiments, the source/drain structures 170B are made of a semiconductor material (e.g., silicon or silicon carbide). The source/drain structures 170B are doped with N-type dopants, such as the Group VA element, in accordance with some embodiments. The Group VA element includes phosphor (P), antimony (Sb), or another suitable Group VA material. The source/drain structures 170B are formed using an epitaxial process, in accordance with some embodiments. In some embodiments, the source/drain structures 170A and 170B are formed in the same epitaxial process and therefore the source/drain structures 170A and 170B are made of the same material.

In some other embodiments, the source/drain structures 170A and 170B are formed in different epitaxial processes, and the source/drain structures 170A and 170B are made of different materials. In some embodiments, the trenches 120r2 are covered by a mask layer (not shown) during the formation of the source/drain structures 170A, and the mask layer is removed after the formation of the source/drain structures 170A. In some embodiments, the source/drain structures 170A are covered by a mask layer (not shown) during the formation of the source/drain structures 170B, and the mask layer is removed after the formation of the source/drain structures 170B.

As shown in FIG. 1L, a dielectric layer 180 is formed over the source/drain structures 170A and 170B, in accordance with some embodiments. The dielectric layer 180 includes a dielectric material such as an oxide-containing material (e.g., silicon oxide), an oxynitride-containing material (e.g., silicon oxynitride), a low-k material, a porous dielectric material, glass, or a combination thereof, in accordance with some embodiments.

The glass includes borosilicate glass (PSG), phosphoric silicate glass (PSG), borophosphosilicate glass (BPSG), fluorinated silicate glass (FSG), or a combination thereof, in accordance with some embodiments. The dielectric layer 180 is formed by a deposition process (e.g., a chemical vapor deposition process) and a planarization process (e.g., a chemical mechanical polishing process), in accordance with some embodiments.

As shown in FIGS. 1K and 1L, the gate stacks 140A and 140B are removed, in accordance with some embodiments. The removal process forms trenches 151b in the gate spacer 151, in accordance with some embodiments. As shown in FIGS. 1K and 1L, the nanostructures 123A, 125A, 125B, 127A, 127B, 129A, and 129B are removed through the trenches 151b, in accordance with some embodiments.

The removal process forms gaps G in the nanostructure stacks 120A and 120B, in accordance with some embodiments. The gaps G in the nanostructure stack 120A are between the spacer layer 152 and the nanostructures 124A, 126A, 128A, and 130A, in accordance with some embodiments. The gaps G in the nanostructure stack 120B are between the nanostructures 124B, 126B, 128B, and 130B, in accordance with some embodiments.

The removal process for removing the gate stacks 140A and 140B, and the nanostructures 121A, 121B, 123A, 123B, 125A, 125B, 127A, 127B, 129A, and 129B includes an etching process such as a wet etching process or a dry etching process, in accordance with some embodiments.

As shown in FIG. 1M, metal gate stacks 190A and 190B are formed in the trenches 151b of the gate spacer 151 and the gaps G of the nanostructure stacks 120A and 120B, in accordance with some embodiments. The metal gate stack 190A is in direct contact with the spacer layer 152, in accordance with some embodiments.

The nanostructures 124A, 126A, 128A, and 130A pass through the metal gate stack 190A, in accordance with some embodiments. The spacer layer 152 separates the metal gate stack 190A, the nanostructures 124A, 126A, 128A, and 130A, and the source/drain structures 170A from the substrate 110, in accordance with some embodiments.

The metal gate stack 190A includes a gate dielectric layer 192A, a work function metal layer 194A, and a gate electrode 196A, in accordance with some embodiments. The gate dielectric layer 192A is conformally formed in the trench 151b of the gate spacer 151 and the gaps G of the nanostructure stack 120A, in accordance with some embodiments. The gate dielectric layer 192A is made of a high-K material, such as HfO₂, La₂O₃, CaO, ZrO₂, HfZrO₂, or Al₂O₃, in accordance with some embodiments. The gate dielectric layer 192A is formed using an atomic layer deposition process or another suitable process.

The work function metal layer 194A is conformally formed over the gate dielectric layer 192A, in accordance with some embodiments. The work function metal layer 194A provides a desired work function for transistors to enhance device performance including improved threshold voltage.

In the embodiments of forming an NMOS transistor, the work function metal layer 194A can be a metal capable of providing a work function value suitable for the device, such as equal to or less than about 4.5 eV. The work function metal layer 194A is made of metal, metal carbide, metal nitride, or a combination thereof, in accordance with some embodiments. For example, the work function metal layer 194A is made of tantalum, hafnium carbide, zirconium carbide, tantalum nitride, or a combination thereof.

In the embodiments of forming a PMOS transistor, the work function metal layer 194A can be a metal capable of providing a work function value suitable for the device, such as equal to or greater than about 4.8 eV. The work function metal layer 194A is made of metal, metal carbide, metal nitride, another suitable material, or a combination thereof, in accordance with some embodiments. For example, the work function metal layer 194A is made of titanium, titanium nitride, another suitable material, or a combination thereof.

The work function metal layer 194A is formed using a deposition process and a removal process, in accordance with some embodiments. The deposition process includes a physical vapor deposition process, a chemical vapor deposition process, an atomic layer deposition process, or a combination thereof, in accordance with some embodiments. The removal process includes a planarization process such as a chemical mechanical polishing process, in accordance with some embodiments.

The gate electrode 196A is formed over the work function metal layer 194A, in accordance with some embodiments. The gate electrode 196A is made of metal, metal nitride, or metal carbide, in accordance with some embodiments. The gate electrode 196A is made of tungsten, titanium nitride, tantalum nitride, titanium aluminide, titanium carbide, or a combination thereof, in accordance with some embodiments.

The gate electrode 196A is formed using an atomic layer deposition process or a chemical vapor deposition process and a removal process, in accordance with some embodiments. The removal process includes a planarization process such as a chemical mechanical polishing process, in accordance with some embodiments.

The metal gate stack 190B includes a gate dielectric layer 192B, a work function metal layer 194B, and a gate electrode 196B, in accordance with some embodiments. The gate dielectric layer 192B is conformally formed in the trench 151b of the gate spacer 151 and the gaps G of the nanostructure stack 120B, in accordance with some embodiments. The gate dielectric layer 192B is made of a high-K material, such as HfO₂, La₂O₃, CaO, ZrO₂, HfZrO₂, or Al₂O₃, in accordance with some embodiments. The gate dielectric layer 192B is formed using an atomic layer deposition process or another suitable process.

The work function metal layer 194B is conformally formed over the gate dielectric layer 192B, in accordance with some embodiments. The work function metal layer 194B provides a desired work function for transistors to enhance device performance including improved threshold voltage.

In the embodiments of forming an NMOS transistor, the work function metal layer 194B can be a metal capable of providing a work function value suitable for the device, such as equal to or less than about 4.5 eV. The work function metal layer 194B is made of metal, metal carbide, metal nitride, or a combination thereof, in accordance with some embodiments. For example, the work function metal layer 194B is made of tantalum, hafnium carbide, zirconium carbide, tantalum nitride, or a combination thereof.

In the embodiments of forming a PMOS transistor, the work function metal layer 194B can be a metal capable of providing a work function value suitable for the device, such as equal to or greater than about 4.8 eV. The work function metal layer 194B is made of metal, metal carbide, metal nitride, another suitable material, or a combination thereof, in accordance with some embodiments. For example, the work function metal layer 194B is made of titanium, titanium nitride, another suitable material, or a combination thereof.

The work function metal layer 194B is formed using a deposition process and a removal process, in accordance with some embodiments. The deposition process includes a physical vapor deposition process, a chemical vapor deposition process, an atomic layer deposition process, or a combination thereof, in accordance with some embodiments. The removal process includes a planarization process such as a chemical mechanical polishing process, in accordance with some embodiments.

The gate electrode 196B is formed over the work function metal layer 194B, in accordance with some embodiments. The gate electrode 196B is made of metal, metal nitride, or metal carbide, in accordance with some embodiments. The gate electrode 196B is made of tungsten, titanium nitride, tantalum nitride, titanium aluminide, titanium carbide, or a combination thereof, in accordance with some embodiments.

The gate electrode 196B is formed using an atomic layer deposition process or a chemical vapor deposition process and a removal process, in accordance with some embodiments. The removal process includes a planarization process such as a chemical mechanical polishing process, in accordance with some embodiments.

In some embodiments, the metal gate stacks 190A and 190B are formed in the same process. In some other embodiments, the metal gate stacks 190A and 190B are formed in different processes. In some embodiments (not shown), an interfacial layer (IL) is formed between the metal gate stack 190A and the nanostructure stack 120A and between the metal gate stack 190B and the nanostructure stack 120B. The interfacial layer is made of an insulating material such as oxides (e.g., silicon oxide), in accordance with some embodiments.

FIG. 1N-1 is a perspective view of the semiconductor device structure of FIG. 1N, in accordance with some embodiments. As shown in FIGS. 1N and 1N-1, portions of the dielectric layer 180 are removed to form through holes 182, in accordance with some embodiments. The through holes 182 pass through the dielectric layer 180 to expose the source/drain structures 170A and 170B respectively, in accordance with some embodiments. The removal process includes performing a photolithography process and an etching process, in accordance with some embodiments.

As shown in FIGS. 1N and 1N-1, a salicidation (self-aligned silicidation) process is performed to form metal silicide structures 210 on and/or in the source/drain structures 170A and 170B, respectively, in accordance with some embodiments. In some embodiments, the metal silicide structures 210 are made of a silicide material of a suitable metal material. The suitable metal material may include cobalt (Co), nickel (Ni), platinum (Pt), titanium (Ti), ytterbium (Yb), molybdenum (Mo), erbium (Er), or a combination thereof. In some embodiments, the salicidation process is optional.

As shown in FIGS. 1N and 1N-1, contact structures 220 are formed in the through holes 182, in accordance with some embodiments. The contact structures 220 are connected to the metal silicide structures 210, in accordance with some embodiments. The contact structures 220 are electrically connected to the source/drain structures 170A and 170B thereunder through the metal silicide structures 210, in accordance with some embodiments.

The contact structures 220 are made of, for example, tungsten or another suitable conductive material, in accordance with some embodiments. The contact structures 220 are formed by, for example, a deposition process and a removal process, in accordance with some embodiments. The deposition process includes a chemical vapor deposition (CVD) process, an atomic layer deposition (ALD) process, or another suitable process, in accordance with some embodiments. The removal process includes a chemical mechanical polishing process, in accordance with some embodiments. In this step, a semiconductor device structure 100 is substantially formed, in accordance with some embodiments.

The metal gate stack 190A and the source/drain structures 170A together form a transistor TR1, in accordance with some embodiments. The metal gate stack 190B and the source/drain structures 170B together form a transistor TR2, in accordance with some embodiments. The method of the application can form different kinds of devices (i.e., the transistors TR1 and TR2) on the same substrate 110 for different applications, in accordance with some embodiments.

In the transistor TR1, the source/drain structures 170A are connected to four nanostructures (i.e., the nanostructures 124A, 126A, 128A, and 130A), in accordance with some embodiments. Therefore, the transistor TR1 can be a high drive current device such as a high performance computer (HPC) device, in accordance with some embodiments.

The spacer layer 152 can prevent the current leakage between the source/drain structures 170A, in accordance with some embodiments. Since the spacer layer 152 separates the metal gate stack 190A and the source/drain structures 170A from the substrate 110, the capacitance between the metal gate stack 190A and the source/drain structures 170A is reduced, in accordance with some embodiments. Therefore, the spacer layer 152 improves the performance of the transistor TR1, in accordance with some embodiments.

In the transistor TR2, the source/drain structures 170B are connected to three nanostructures (i.e., the nanostructures 126B, 128B, and 130B) and a semiconductor-on-insulator (SOI) structure (i.e., the nanostructure 124B and the spacer layer 154), in accordance with some embodiments. The transistor TR2 can be a high performance device such as a high performance computer (HPC) device, in accordance with some embodiments.

Since the source/drain structures 170B are smaller than (or thinner than) the source/drain structures 170A, the capacitance between the source/drain structures 170B and the metal gate stack 190B is less than the capacitance between the source/drain structures 170A and the metal gate stack 190A, in accordance with some embodiments.

The spacer layer 154 can prevent the current leakage between the source/drain structures 170B, in accordance with some embodiments. Since the spacer layer 154 separates the metal gate stack 190B and the source/drain structures 170B from the substrate 110, the capacitance between the metal gate stack 190B and the source/drain structures 170B is reduced, in accordance with some embodiments. Therefore, the spacer layer 154 improves the performance of the transistor TR2, in accordance with some embodiments.

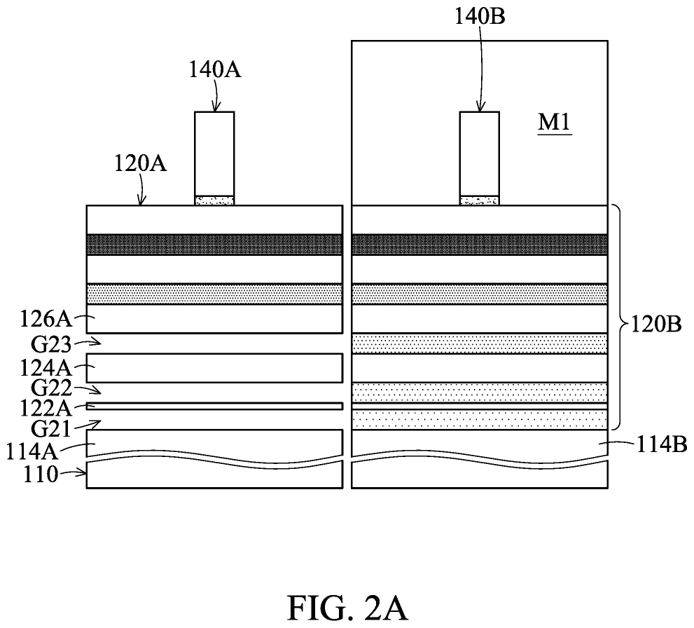

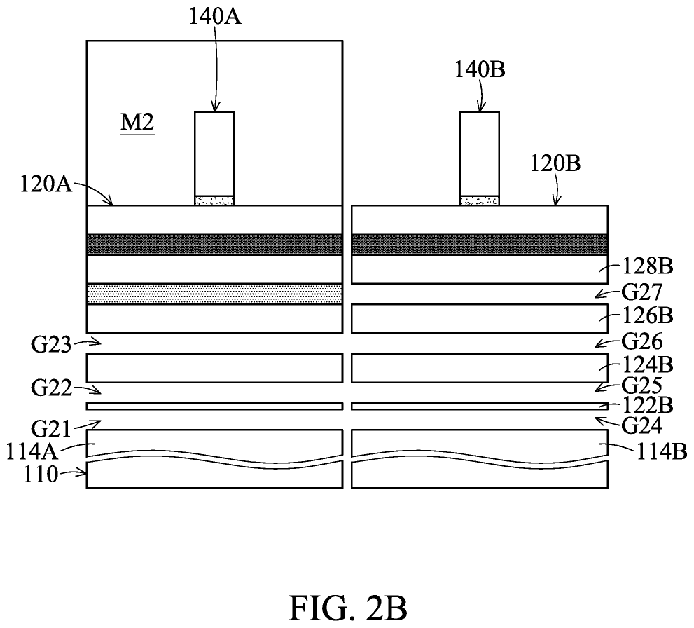

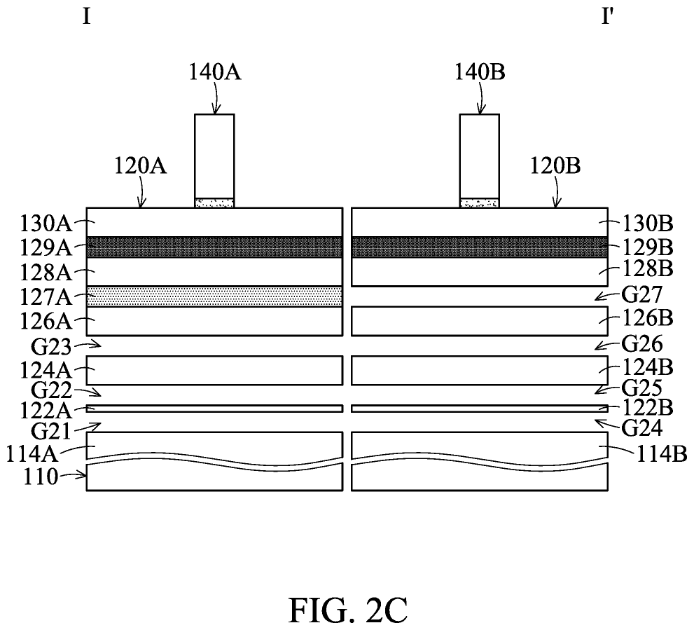

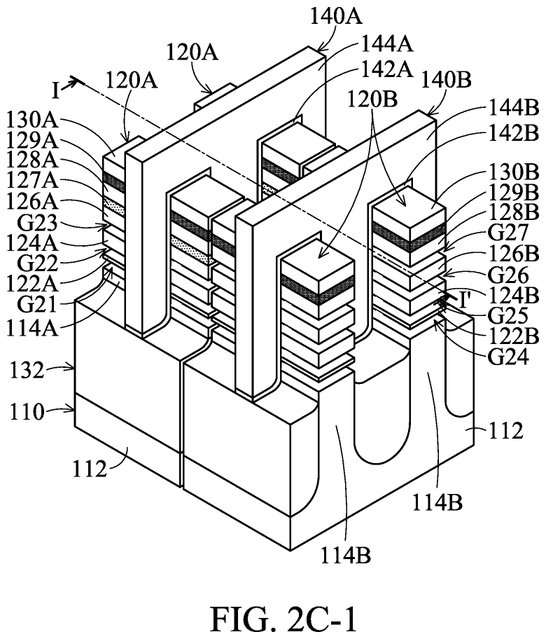

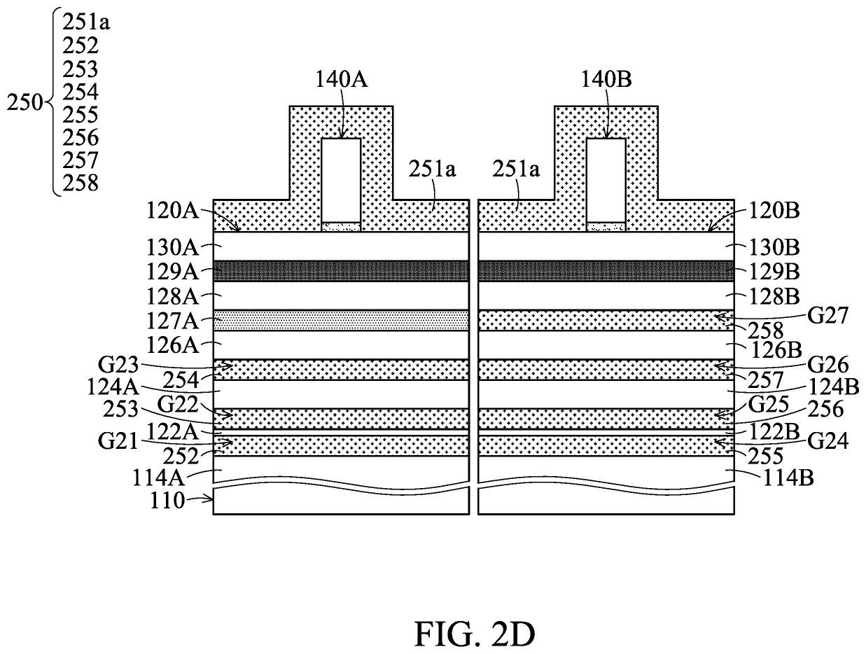

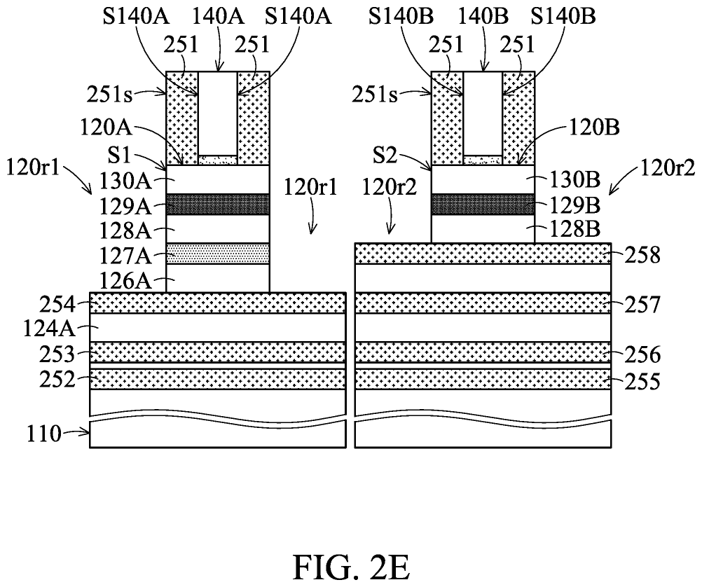

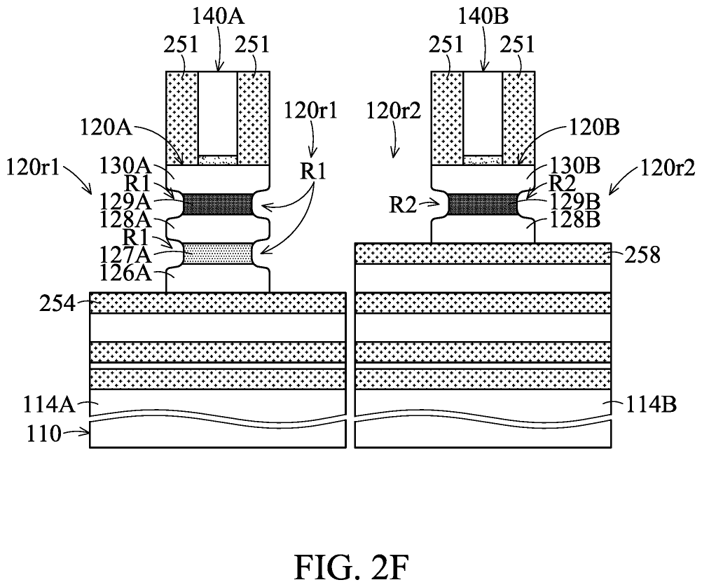

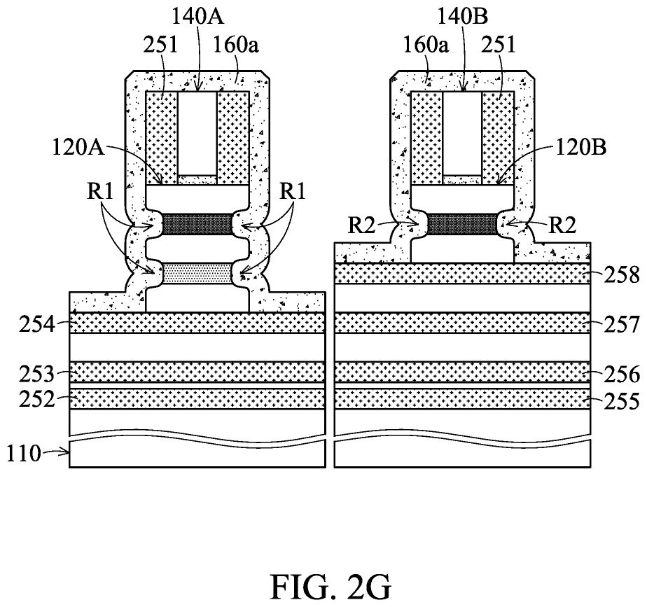

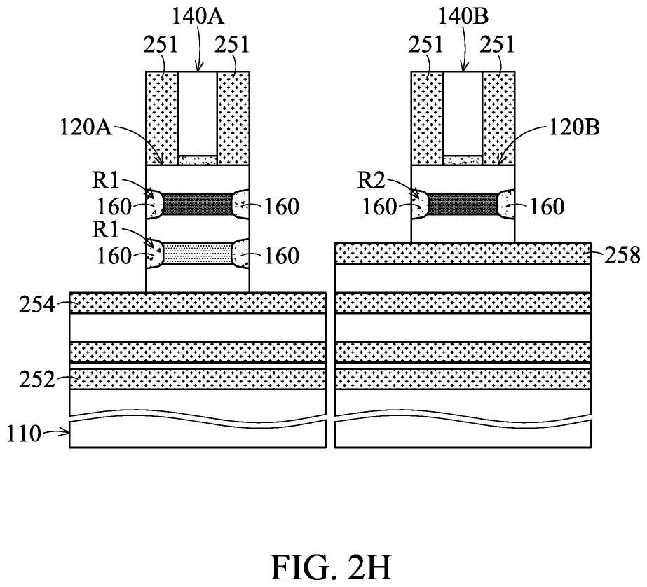

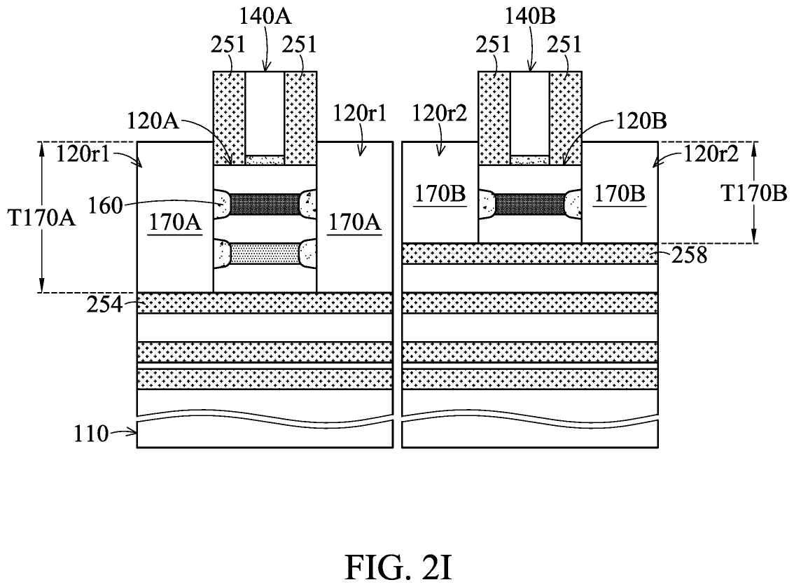

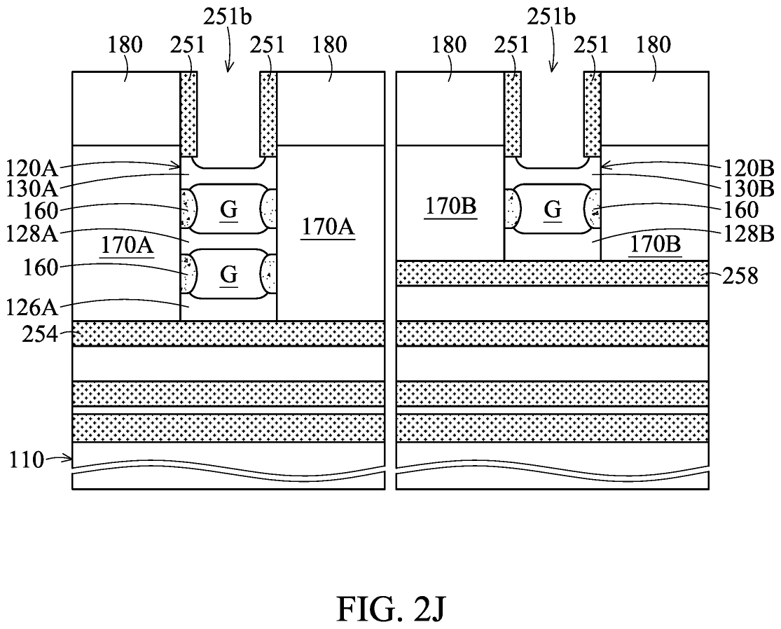

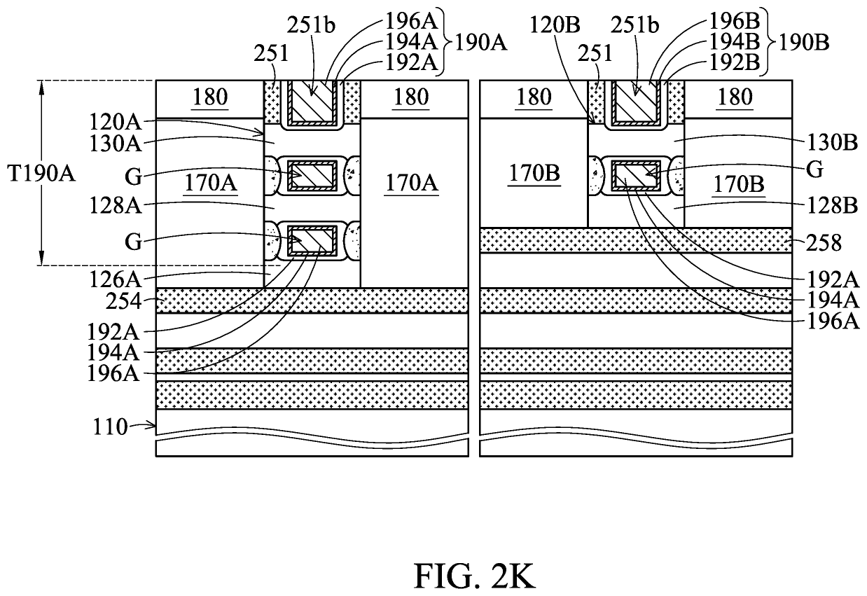

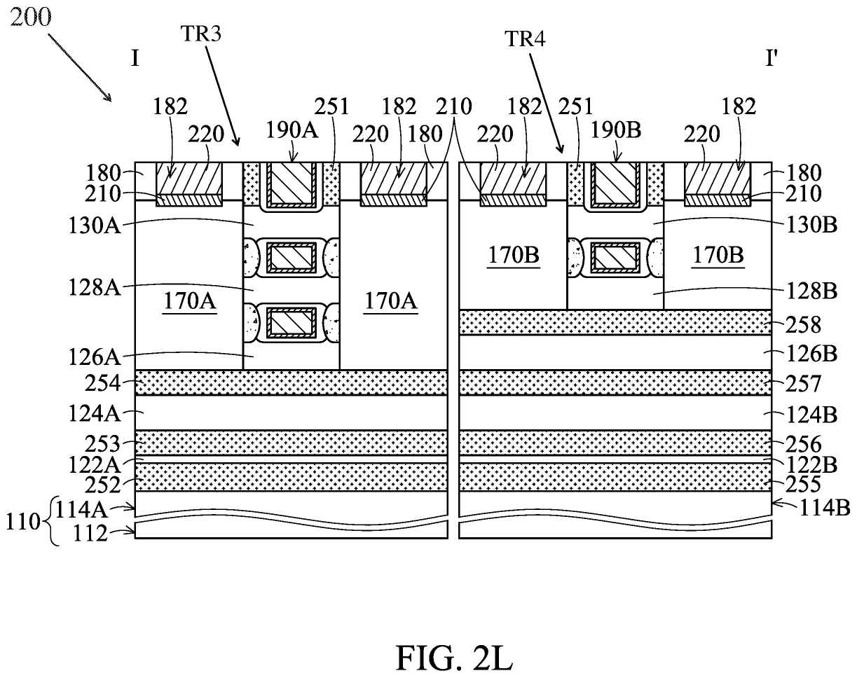

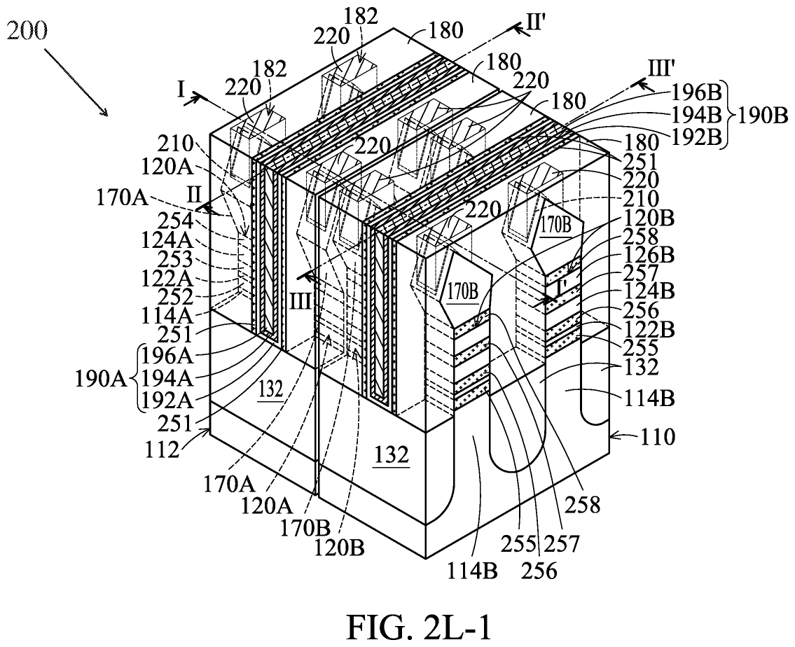

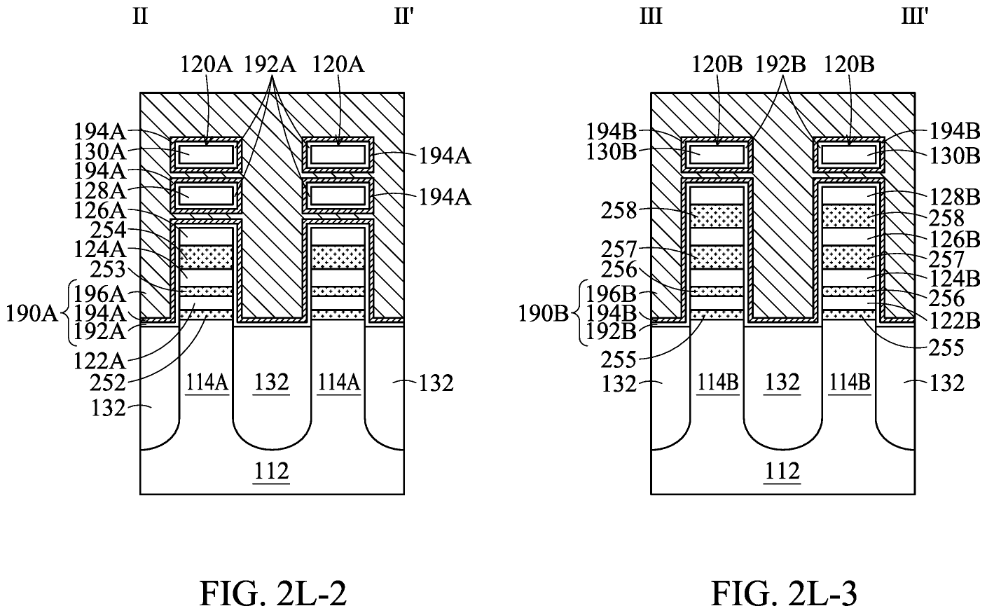

FIG. 1N-2 is a cross-sectional view illustrating the semiconductor device structure along a sectional line II-II′ in FIG. 1N-1, in accordance with some embodiments. As shown in FIG. 1N-2, the metal gate stack 190A is wrapped around the nanostructures 124A, 126A, 128A, and 130A, in accordance with some embodiments.

FIG. 1N-3 is a cross-sectional view illustrating the semiconductor device structure along a sectional line in FIG. 1N-1, in accordance with some embodiments. As shown in FIG. 1N-3, the metal gate stack 190B is wrapped around the nanostructures 122B, 124B, 126B, 128B, and 130B, in accordance with some embodiments.

FIGS. 2A-2L are cross-sectional views of various stages of a process for forming a semiconductor device structure, in accordance with some embodiments. After the step of FIG. 1B, as shown in FIG. 2A, the nanostructures 121A, 123A, and 125A are removed to form gaps G21, G22, and G23 in the nanostructure stack 120A, in accordance with some embodiments.

The gap G21 is between the fin 114A and the nanostructure 122A, in accordance with some embodiments. The gap G22 is between the nanostructures 122A and 124A, in accordance with some embodiments. The gap G23 is between the nanostructures 124A and 126A, in accordance with some embodiments. The removal process includes an etching process such as a dry etching process or a wet etching process, in accordance with some embodiments.

As shown in FIG. 2B, the mask layer M1 is removed, in accordance with some embodiments. As shown in FIG. 2B, a mask layer M2 is formed over the gate stack 140A, the nanostructure stack 120A, and the fin 114A, in accordance with some embodiments. The mask layer M2 is made of a material, which is different from that of the gate stacks 140A and 140B, the nanostructure stacks 120A and 120B, and the fins 114A and 114B, in accordance with some embodiments. The material includes nitrides (e.g., SiN) or polymer (e.g., a photoresist material), in accordance with some embodiments.

As shown in FIG. 2B, the nanostructures 121B, 123B, 125B, and 127B are removed to form gaps G24, G25, G26, and G27 in the nanostructure stack 120B, in accordance with some embodiments. The gap G24 is between the fin 114B and the nanostructure 122B, in accordance with some embodiments. The gap G25 is between the nanostructures 122B and 124B, in accordance with some embodiments. The gap G26 is between the nanostructures 124B and 126B, in accordance with some embodiments. The gap G27 is between the nanostructures 126B and 128B, in accordance with some embodiments. The removal process includes an etching process such as a dry etching process or a wet etching process, in accordance with some embodiments.

FIG. 2C-1 is a perspective view of the semiconductor device structure of FIG. 2C, in accordance with some embodiments. As shown in FIGS. 2C and 2C-1, the mask layer M2 is removed, in accordance with some embodiments.

As shown in FIG. 2D, a dielectric layer 250 is formed over the gate stacks 140A and 140B and the nanostructure stacks 120A and 120B and in the gaps G21, G22, and G23 of the nanostructure stack 120A and the gaps G24, G25, G26, and G27 of the nanostructure stack 120B, in accordance with some embodiments. The dielectric layer 250 includes a gate spacer layer 251a and spacer layers 252, 253, 254, 255, 256, 257, and 258, in accordance with some embodiments.

The gate spacer layer 251a is over the gate stacks 140A and 140B and the nanostructure stacks 120A and 120B, in accordance with some embodiments. The spacer layers 252, 253, 254, 255, 256, 257, and 258 are in the gaps G21, G22, G23, G24, G25, G26, and G27 respectively, in accordance with some embodiments. The nanostructure 122A is between the spacer layers 252 and 253, in accordance with some embodiments. The nanostructure 124A is between the spacer layers 253 and 254, in accordance with some embodiments.

The nanostructure 122B is between the spacer layers 255 and 256, in accordance with some embodiments. The nanostructure 124B is between the spacer layers 256 and 257, in accordance with some embodiments. The nanostructure 126B is between the spacer layers 257 and 258, in accordance with some embodiments. The spacer layer 255 is between the nanostructure 122B and the fin 114B of the substrate 110, in accordance with some embodiments. The nanostructure 122A or 122B is thinner than the spacer layer 252, 253, 254, 255, 256, 257, or 258, in accordance with some embodiments.

The dielectric layer 250 includes insulating materials, such as silicon oxide, silicon nitride, silicon oxynitride, or silicon carbide, in accordance with some embodiments. The dielectric layer 250 is made of a material different from that of the gate stacks 140A and 140B, in accordance with some embodiments.

The formation of the dielectric layer 250 includes a deposition process, in accordance with some embodiments. The deposition process includes a chemical vapor deposition (CVD) process, a high density plasma chemical vapor deposition (HDPCVD) process, a flowable chemical vapor deposition (FCVD) process, or a combination thereof, in accordance with some embodiments.

As shown in FIG. 2E, portions of the gate spacer layer 251a are removed, in accordance with some embodiments. The remaining gate spacer layer 251a forms a gate spacer 251, in accordance with some embodiments. The gate spacer 251 is over sidewalls S140A of the gate stack 140A and sidewalls S140B of the gate stack 140B, in accordance with some embodiments.

The gate spacer 251 surrounds the gate stacks 140A and 140B, in accordance with some embodiments. The gate spacer 251 is positioned over the nanostructure stacks 120A and 120B, in accordance with some embodiments. The removal process includes an etching process such as an anisotropic etching process (e.g., a dry etching process), in accordance with some embodiments.

As shown in FIG. 2E, end portions of the nanostructures 126A, 127A, 128A, 128B, 129A, 129B, 130A, and 130B, which are not covered by the gate stacks 140A and 140B and the gate spacer 251, are removed, in accordance with some embodiments. The removal process forms trenches 120r1 and 120r2 in the nanostructure stacks 120A and 120B respectively, in accordance with some embodiments.

The trenches 120r1 expose portions of the spacer layer 254, in accordance with some embodiments. The trenches 120r2 expose portions of the spacer layer 258, in accordance with some embodiments. After the removal process, sidewalls S1 of the nanostructure stack 120A are substantially aligned with (or substantially coplanar with) the sidewalls 251s of the gate spacer 251 over the nanostructure stack 120A, in accordance with some embodiments.

In some embodiments, sidewalls S2 of the nanostructure stack 120B are substantially aligned with (or substantially coplanar with) the sidewalls 251s of the gate spacer 251 over the nanostructure stack 120B, in accordance with some embodiments. The removal process includes an etching process, in accordance with some embodiments. The etching process includes an anisotropic etching process such as a dry etching process, in accordance with some embodiments.

As shown in FIG. 2F, portions of the nanostructures 127A, 129A, and 129B are removed through the trenches 120r1 and 120r2, in accordance with some embodiments. The removal process forms recesses R1 and R2 in the nanostructure stacks 120A and 120B respectively, in accordance with some embodiments.

The recesses R1 are between the nanostructures 126A, 128A, and 130A, in accordance with some embodiments. The recesses R2 are between the nanostructures 128B and 130B, in accordance with some embodiments. The removal process further removes portions of the nanostructures 126A, 128A, 128B, 130A, and 130B, in accordance with some embodiments. The removal process includes an etching process such as a dry etching process or a wet etching process, in accordance with some embodiments.

As shown in FIG. 2G, an inner spacer layer 160a is formed over the gate stacks 140A and 140B, the nanostructure stacks 120A and 120B, and the spacer layers 254 and 258 and in the recesses R1 and R2 of the nanostructure stacks 120A and 120B, in accordance with some embodiments. The inner spacer layer 160a is made of an insulating material, such as an oxide-containing material (e.g., silicon oxide), a nitride-containing material (e.g., silicon nitride), an oxynitride-containing material (e.g., silicon oxynitride), a carbide-containing material (e.g., silicon carbide), a high-k material (e.g., HfO₂, ZrO₂, HfZrO₂, or Al₂O₃), or a low-k material, in accordance with some embodiments.

In some embodiments, the inner spacer layer 160a is formed using a deposition process. The deposition process includes a physical vapor deposition process, a chemical vapor deposition process, an atomic layer deposition process, or the like, in accordance with some embodiments.

As shown in FIG. 2H, portions of the inner spacer layer 160a outside of the recesses R1 and R2 of the nanostructure stacks 120A and 120B are removed, in accordance with some embodiments. The remaining inner spacer layer 160a forms an inner spacer 160, in accordance with some embodiments. The inner spacer 160 is in the recesses R1 and R2, in accordance with some embodiments.

The inner spacer 160 is in direct contact with the nanostructure stacks 120A and 120B, in accordance with some embodiments. The removal process includes an etching process such as an anisotropic etching process (e.g., a dry etching process), in accordance with some embodiments.

As shown in FIG. 2I, source/drain structures 170A are formed in the trenches 120r1 and over the spacer layer 254, in accordance with some embodiments. The nanostructure stack 120A is between the source/drain structures 170A, in accordance with some embodiments.

The source/drain structures 170A are in direct contact with (or connected to) the nanostructure stack 120A, the gate spacer 251, and the inner spacer 160, in accordance with some embodiments. The source/drain structures 170A are in direct contact with the spacer layer 254, in accordance with some embodiments. The source/drain structures 170A are used to be a source structure and a drain structure, in accordance with some embodiments.

In some embodiments, the source/drain structures 170A are made of a semiconductor material (e.g., silicon germanium). In some embodiments, the source/drain structures 170A are doped with P-type dopants. The P-type dopants include the Group IIIA element, in accordance with some embodiments. The Group IIIA element includes boron or another suitable material.

In some other embodiments, the source/drain structures 170A are made of a semiconductor material (e.g., silicon or silicon carbide). The source/drain structures 170A are doped with N-type dopants, such as the Group VA element, in accordance with some embodiments. The Group VA element includes phosphor (P), antimony (Sb), or another suitable Group VA material. The source/drain structures 170A are formed using an epitaxial process, in accordance with some embodiments.

As shown in FIG. 2I, source/drain structures 170B are formed in the trenches 120r2 and over the spacer layer 258, in accordance with some embodiments. The nanostructure stack 120B is between the source/drain structures 170B, in accordance with some embodiments. The source/drain structures 170B are in direct contact with (or connected to) the nanostructure stack 120B and the gate spacer 251, in accordance with some embodiments.

The source/drain structures 170B are in direct contact with the spacer layer 258, in accordance with some embodiments. The source/drain structures 170B are used to be a source structure and a drain structure, in accordance with some embodiments. The thickness T170A of the source/drain structure 170A is greater than the thickness T170B of the source/drain structure 170B, in accordance with some embodiments.

In some embodiments, the source/drain structures 170B are made of a semiconductor material (e.g., silicon germanium). In some embodiments, the source/drain structures 170B are doped with P-type dopants. The P-type dopants include the Group IIIA element, in accordance with some embodiments. The Group IIIA element includes boron or another suitable material.

In some other embodiments, the source/drain structures 170B are made of a semiconductor material (e.g., silicon or silicon carbide). The source/drain structures 170B are doped with N-type dopants, such as the Group VA element, in accordance with some embodiments. The Group VA element includes phosphor (P), antimony (Sb), or another suitable Group VA material.

The source/drain structures 170B are formed using an epitaxial process, in accordance with some embodiments. In some embodiments, the source/drain structures 170A and 170B are formed in the same epitaxial process and therefore the source/drain structures 170A and 170B are made of the same material.

In some other embodiments, the source/drain structures 170A and 170B are formed in different epitaxial processes, and the source/drain structures 170A and 170B are made of different materials. In some embodiments, the trenches 120r2 are covered by a mask layer (not shown) during the formation of the source/drain structures 170A, and the mask layer is removed after the formation of the source/drain structures 170A. In some embodiments, the source/drain structures 170A are covered by a mask layer (not shown) during the formation of the source/drain structures 170B, and the mask layer is removed after the formation of the source/drain structures 170B.

As shown in FIG. 2J, a dielectric layer 180 is formed over the source/drain structures 170A and 170B, in accordance with some embodiments. The dielectric layer 180 includes a dielectric material such as an oxide-containing material (e.g., silicon oxide), an oxynitride-containing material (e.g., silicon oxynitride), a low-k material, a porous dielectric material, glass, or a combination thereof, in accordance with some embodiments.

The glass includes borosilicate glass (PSG), phosphoric silicate glass (PSG), borophosphosilicate glass (BPSG), fluorinated silicate glass (FSG), or a combination thereof, in accordance with some embodiments. The dielectric layer 180 is formed by a deposition process (e.g., a chemical vapor deposition process) and a planarization process (e.g., a chemical mechanical polishing process), in accordance with some embodiments.

As shown in FIGS. 21 and 2J, the gate stacks 140A and 140B are removed, in accordance with some embodiments. The removal process forms trenches 251b in the gate spacer 251, in accordance with some embodiments. As shown in FIGS. 21 and 2J, the nanostructures 127A, 129A, and 129B are removed through the trenches 251b, in accordance with some embodiments.

The removal process forms gaps G in the nanostructure stacks 120A and 120B, in accordance with some embodiments. The gaps G in the nanostructure stack 120A are between the nanostructures 126A, 128A, and 130A, in accordance with some embodiments. The gap G in the nanostructure stack 120B is between the nanostructures 128B and 130B, in accordance with some embodiments. The removal process includes an etching process such as a wet etching process or a dry etching process, in accordance with some embodiments.

As shown in FIG. 2K, metal gate stacks 190A and 190B are formed in the trenches 251b of the gate spacer 251 and the gaps G of the nanostructure stacks 120A and 120B, in accordance with some embodiments. The nanostructures 126A, 128A, and 130A pass through the metal gate stack 190A, in accordance with some embodiments. The spacer layer 254 separates the metal gate stack 190A, the nanostructures 126A, 128A, and 130A, and the source/drain structures 170A from the substrate 110, in accordance with some embodiments.

The metal gate stack 190A includes a gate dielectric layer 192A, a work function metal layer 194A, and a gate electrode 196A, in accordance with some embodiments. The gate dielectric layer 192A is conformally formed in the trench 251b of the gate spacer 251 and the gaps G of the nanostructure stack 120A, in accordance with some embodiments. The work function metal layer 194A is conformally formed over the gate dielectric layer 192A, in accordance with some embodiments. The gate electrode 196A is formed over the work function metal layer 194A, in accordance with some embodiments.

The metal gate stack 190B includes a gate dielectric layer 192B, a work function metal layer 194B, and a gate electrode 196B, in accordance with some embodiments. The gate dielectric layer 192B is conformally formed in the trench 251b of the gate spacer 251 and the gap G of the nanostructure stack 120B, in accordance with some embodiments. The work function metal layer 194B is conformally formed over the gate dielectric layer 192B, in accordance with some embodiments.

The gate electrode 196B is formed over the work function metal layer 194B, in accordance with some embodiments. In some embodiments, the metal gate stacks 190A and 190B are formed in the same process. In some other embodiments, the metal gate stacks 190A and 190B are formed in different processes.

FIG. 2L-1 is a perspective view of the semiconductor device structure of FIG. 2L, in accordance with some embodiments. As shown in FIGS. 2L and 2L-1, portions of the dielectric layer 180 are removed to form through holes 182, in accordance with some embodiments. The through holes 182 pass through the dielectric layer 180 to expose the source/drain structures 170A and 170B respectively, in accordance with some embodiments. The removal process includes performing a photolithography process and an etching process, in accordance with some embodiments.

As shown in FIGS. 2L and 2L-1, a salicidation (self-aligned silicidation) process is performed to form metal silicide structures 210 on and/or in the source/drain structures 170A and 170B, respectively, in accordance with some embodiments. In some embodiments, the metal silicide structures 210 are made of a silicide material of a suitable metal material. The suitable metal material may include cobalt (Co), nickel (Ni), platinum (Pt), titanium (Ti), ytterbium (Yb), molybdenum (Mo), erbium (Er), or a combination thereof. In some embodiments, the salicidation process is optional.

As shown in FIGS. 2L and 2L-1, contact structures 220 are formed in the through holes 182, in accordance with some embodiments. The contact structures 220 are connected to the metal silicide structures 210, in accordance with some embodiments. The contact structures 220 are electrically connected to the source/drain structures 170A and 170B thereunder through the metal silicide structures 210, in accordance with some embodiments.

The contact structures 220 are made of, for example, tungsten or another suitable conductive material, in accordance with some embodiments. The contact structures 220 are formed by, for example, a deposition process and a removal process, in accordance with some embodiments. The deposition process includes a chemical vapor deposition (CVD) process, an atomic layer deposition (ALD) process, or another suitable process, in accordance with some embodiments. The removal process includes a chemical mechanical polishing process, in accordance with some embodiments. In this step, a semiconductor device structure 200 is substantially formed, in accordance with some embodiments.

The metal gate stack 190A and the source/drain structures 170A together form a transistor TR3, in accordance with some embodiments. The metal gate stack 190B and the source/drain structures 170B together form a transistor TR4, in accordance with some embodiments. The method of the application can form different kinds of devices (i.e., the transistors TR3 and TR4) on the same substrate 110 for different applications, in accordance with some embodiments.

In the transistor TR3, the source/drain structures 170A are connected to two nanostructures (i.e., the nanostructures 128A and 130A) and a semiconductor-on-insulator (SOI) structure (i.e., the nanostructure 126A and the spacer layer 254), in accordance with some embodiments. The transistor TR3 can be a high power efficiency device such as a system-on-chip (SoC) device, in accordance with some embodiments.

Since the source/drain structures 170A of the transistor TR3 are smaller than (or thinner than) the source/drain structures 170A of the transistor TR1, the capacitance between the source/drain structures 170A and the metal gate stack 190A of the transistor TR3 is less than the capacitance between the source/drain structures 170A and the metal gate stack 190A of the transistor TR1, in accordance with some embodiments.

Since the number of the nanostructures connected to the source/drain structures 170A of the transistor TR3 is less than the number of the nanostructures connected to the source/drain structures 170A of the transistor TR1 (or the number of the nanostructures connected to the source/drain structures 170B of the transistor TR2), the leakage current between the source/drain structures 170A of the transistor TR3 is less than that between the source/drain structures 170A of the transistor TR1 (or that between the source/drain structures 170B of the transistor TR2), in accordance with some embodiments.

The spacer layer 254 can prevent the current leakage between the source/drain structures 170A, in accordance with some embodiments. Since the spacer layer 254 separates the metal gate stack 190A and the source/drain structures 170A from the substrate 110, the capacitance between the metal gate stack 190A and the source/drain structures 170A is reduced, in accordance with some embodiments. Therefore, the spacer layer 254 improves the performance of the transistor TR3, in accordance with some embodiments.

In the transistor TR4, the source/drain structures 170B are connected to one nanostructures (i.e., the nanostructure 130B) and a semiconductor-on-insulator (SOI) structure (i.e., the nanostructure 128B and the spacer layer 258), in accordance with some embodiments. The transistor TR4 can be a low power consumption device such as a wearable device, in accordance with some embodiments. The low power consumption device has the lowest leakage current, in accordance with some embodiments.

Since the source/drain structures 170B of the transistor TR4 are smaller than (or thinner than) the source/drain structures 170A of the transistor TR3, the capacitance between the source/drain structures 170B and the metal gate stack 190B of the transistor TR4 is less than the capacitance between the source/drain structures 170A and the metal gate stack 190A of the transistor TR3, in accordance with some embodiments.

Since the number of the nanostructures connected to the source/drain structures 170B of the transistor TR4 is less than the number of the nanostructures connected to the source/drain structures 170A of the transistor TR3, the leakage current between the source/drain structures 170B of the transistor TR4 is less than that between the source/drain structures 170A of the transistor TR3, in accordance with some embodiments.

The spacer layer 258 can prevent the current leakage between the source/drain structures 170B, in accordance with some embodiments. Since the spacer layer 258 separates the metal gate stack 190B and the source/drain structures 170B from the substrate 110, the capacitance between the metal gate stack 190B and the source/drain structures 170B is reduced, in accordance with some embodiments. Therefore, the spacer layer 258 improves the performance of the transistor TR4, in accordance with some embodiments.

FIG. 2L-2 is a cross-sectional view illustrating the semiconductor device structure along a sectional line II-II′ in FIG. 2L-1, in accordance with some embodiments. As shown in FIG. 2L-2, the metal gate stack 190A is wrapped around the nanostructures 122A, 124A, 126A, 128A, and 130A, in accordance with some embodiments.

FIG. 2L-3 is a cross-sectional view illustrating the semiconductor device structure along a sectional line in FIG. 2L-1, in accordance with some embodiments. As shown in FIG. 2L-3, the metal gate stack 190B is wrapped around the nanostructures 122B, 124B, 126B, 128B, and 130B, in accordance with some embodiments.

Processes and materials for forming the semiconductor device structure 200 may be similar to, or the same as, those for forming the semiconductor device structure 100 described above. Elements designated by the same or similar reference numbers as those in FIGS. 1A to 2L-3 have the same or similar structures and the materials. Therefore, the detailed descriptions thereof will not be repeated herein.

In accordance with some embodiments, semiconductor device structures and methods for forming the same are provided. The methods (for forming the semiconductor device structure) form a spacer layer between nanostructures of a nanostructure stack to adjust the number of the nanostructures, which are connected to source/drain structures. Therefore, the methods can adjust the number of the nanostructures connected to source/drain structures according to different applications. Furthermore, the methods can form different devices for different applications in/on the same substrate. The spacer layer can reduce the capacitance between the source/drain structures and between a gate stack and the source/drain structures. The spacer layer can prevent the current leakage between the source/drain structures. Therefore, the spacer layer improves the performance of the semiconductor device structure.

In accordance with some embodiments, a method for forming a semiconductor device structure is provided. The method includes providing a substrate. The method includes forming a nanostructure stack over the substrate. The nanostructure stack includes a first nanostructure, a second nanostructure, a third nanostructure, and a fourth nanostructure sequentially formed over the substrate. The method includes forming a gate stack over the nanostructure stack and the substrate. The method includes removing the first nanostructure forming a first gap between the substrate and the second nanostructure. The method includes forming a first spacer layer in the first gap and a gate spacer over a sidewall of the gate stack. The method includes partially removing the nanostructure stack, which is not covered by the gate stack and the gate spacer, to form a first trench in the nanostructure stack. The method includes forming a source/drain structure in the first trench and over the first spacer layer.

In accordance with some embodiments, a method for forming a semiconductor device structure is provided. The method includes providing a substrate having a base and a fin over the base. The method includes forming a nanostructure stack over the fin. The nanostructure stack includes a first nanostructure, a second nanostructure, a third nanostructure, and a fourth nanostructure sequentially formed over the fin, and the second nanostructure is thinner than the first nanostructure. The method includes forming a gate stack over the nanostructure stack and the fin. The method includes removing the first nanostructure forming a first gap between the fin and the second nanostructure. The method includes forming a spacer layer in the first gap and a gate spacer over a sidewall of the gate stack.

In accordance with some embodiments, a semiconductor device structure is provided. The semiconductor device structure includes a substrate. The semiconductor device structure includes a first spacer layer over the substrate. The semiconductor device structure includes a gate stack over the first spacer layer and the substrate. The semiconductor device structure includes a first nanostructure passing through the gate stack. The semiconductor device structure includes a source/drain structure over the first spacer layer and connected to the first nanostructure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
providing a substrate;
forming a nanostructure stack over the substrate, wherein the nanostructure stack comprises a first nanostructure, a second nanostructure, a third nanostructure, and a fourth nanostructure sequentially formed over the substrate;
forming a gate stack over the nanostructure stack and the substrate;
removing the first nanostructure forming a first gap between the substrate and the second nanostructure;
forming a first spacer layer in the first gap and a gate spacer over a sidewall of the gate stack;
partially removing the nanostructure stack, which is not covered by the gate stack and the gate spacer, to form a first trench in the nanostructure stack; and
forming a source/drain structure in the first trench and over the first spacer layer.

2. The method for forming the semiconductor device structure as claimed in claim 1, further comprising:
after partially removing the nanostructure stack and before forming the source/drain structure in the first trench and over the first spacer layer, removing an end portion of the third nanostructure through the first trench to form a recess in the nanostructure stack, wherein the recess is between the second nanostructure and the fourth nanostructure; and
forming an inner spacer in the recess.

3. The method for forming the semiconductor device structure as claimed in claim 2, wherein the removing of the end portion of the third nanostructure comprises:
removing a portion of the second nanostructure, wherein the inner spacer is in direct contact with the first spacer layer.

4. The method for forming the semiconductor device structure as claimed in claim 1, further comprising:
after forming the source/drain structure in the first trench and over the first spacer layer, removing the gate stack to form a second trench in the gate spacer;
removing the second nanostructure and the third nanostructure forming a second gap between the first spacer layer and the fourth nanostructure; and
forming a metal gate stack in the second trench and the second gap, wherein the metal gate stack is wrapped around the fourth nanostructure.

5. The method for forming the semiconductor device structure as claimed in claim 4, wherein the metal gate stack is in direct contact with the first spacer layer.

6. The method for forming the semiconductor device structure as claimed in claim 1, wherein the nanostructure stack further comprises a fifth nanostructure and a sixth nanostructure between the second nanostructure and the third nanostructure, the fifth nanostructure is between the second nanostructure and the sixth nanostructure, and the removing of the first nanostructure comprises:
removing the fifth nanostructure forming a second gap between the second nanostructure and the sixth nanostructure, wherein
the forming of the first spacer layer in the first gap and the gate spacer over a sidewall of the gate stack comprises:
forming a second spacer layer in the second gap.

7. The method for forming the semiconductor device structure as claimed in claim 6, wherein the first trench of the nanostructure stack exposes a portion of the second spacer layer.

8. The method for forming the semiconductor device structure as claimed in claim 7, wherein the source/drain structure is in direct contact with the second spacer layer.

9. The method for forming the semiconductor device structure as claimed in claim 1, wherein the first trench of the nanostructure stack exposes a portion of the first spacer layer, and the source/drain structure is in direct contact with the first spacer layer.

10. The method for forming the semiconductor device structure as claimed in claim 1, wherein the first nanostructure and the third nanostructure comprise silicon germanium, and a first germanium concentration of the first nanostructure is greater than a second germanium concentration of the third nanostructure.

11. A method for forming a semiconductor device structure, comprising:
providing a substrate having a base and a fin over the base;
forming a nanostructure stack over the fin, wherein the nanostructure stack comprises a first nanostructure, a second nanostructure, a third nanostructure, and a fourth nanostructure sequentially formed over the fin, and the second nanostructure is thinner than the first nanostructure;
forming a gate stack over the nanostructure stack and the fin;
removing the first nanostructure forming a first gap between the fin and the second nanostructure; and
forming a spacer layer in the first gap and a gate spacer over a sidewall of the gate stack.

12. The method for forming the semiconductor device structure as claimed in claim 11, wherein the first nanostructure is doped with a group VA element.

13. The method for forming the semiconductor device structure as claimed in claim 11, wherein the third nanostructure is doped with a group IIIA element.

14. The method for forming the semiconductor device structure as claimed in claim 11, further comprising:
partially removing the nanostructure stack, which is not covered by the gate stack and the gate spacer, to form a trench in the nanostructure stack, wherein the trench exposes a portion of the spacer layer; and
forming a source/drain structure in the trench.

15. The method for forming the semiconductor device structure as claimed in claim 14, wherein the source/drain structure is in direct contact with the spacer layer.

16. A semiconductor device structure, comprising:
a substrate;
a first spacer layer over the substrate;
a gate stack over the first spacer layer and the substrate;
a first nanostructure passing through the gate stack; and
a source/drain structure over the first spacer layer and connected to the first nano structure.

17. The semiconductor device structure as claimed in claim 16, wherein the first spacer layer separates the gate stack, the first nanostructure, and the source/drain structure from the substrate.

18. The semiconductor device structure as claimed in claim 16, wherein the gate stack is in direct contact with the first spacer layer.

19. The semiconductor device structure as claimed in claim 16, further comprising:
a second nanostructure between the first spacer layer and the substrate; and
a second spacer layer between the second nanostructure and the substrate.

20. The semiconductor device structure as claimed in claim 19, wherein the second nanostructure is thinner than the first nanostructure.
